(19) United States
(12) Patent Application Publication
(10) Pub. No.: US 2025/0112162 A1
(43) Pub. Date: Apr. 3, 2025

(54) DEEP CAVITY METALLIZATION AND FIDUCIAL ARRANGEMENTS FOR EMBEDDED DIE AND ASSEMBLY THEREOF ON INTEGRATED CIRCUIT PACKAGING

(71) Applicant: Intel Corporation, Santa Clara, CA (US)

(72) Inventors: Zheng Kang, Chandler, AZ (US); Tchefor Ndukum, Chandler, AZ (US); Yosuke Kanaoka, Chandler, AZ (US); Jeremy Ecton, Gilbert, AZ (US); Gang Duan, Chandler, AZ (US); Jefferson Kaplan, Chandler, AZ (US); Yonggang Yong Li, Chandler, AZ (US); Minglu Liu, Chandler, AZ (US); Brandon C. Marin, Gilbert, AZ (US); Bai Nie, Chandler, AZ (US); Srinivas Pietambaram, Chandler, AZ (US); Shriya Seshadri, Chandler, AZ (US); Bohan Shan, Chandler, AZ (US); Deniz Turan, Chandler, AZ (US); Vishal Bhimrao Zade, Chandler, AZ (US)

(73) Assignee: Intel Corporation, Santa Clara, CA (US)

(21) Appl. No.: 18/375,469

(22) Filed: Sep. 30, 2023

(51) Int. Cl. H01L 23/538; H01L 21/48; H01L 21/56; H01L 23/00

(52) U.S. Cl. CPC H01L 23/5383; H01L 21/4857; H01L 21/56; H01L 24/16; H01L 24/32; H01L 24/73; H01L 24/81; H01L 2224/16227; H01L 2224/32225; H01L 2224/73204; H01L 2224/81

(57) ABSTRACT

An electronic package comprises a substrate core; one or more dielectric material layers over the substrate core and having a lower dielectric material layer, and a plurality of metallization layers comprising an upper-most metallization layer; an integrated circuit (IC) die embedded within the dielectric material and below the upper-most metallization layer; and at least one conductive feature below and coupled to the IC die. A downwardly facing surface of the conductive feature is located on the lower dielectric material layer and defines a horizontal plane at a junction between the conductive feature and the lower dielectric material layer. The lower dielectric material layer has an upper facing surface facing in a direction of the IC die adjacent the conductive feature that is vertically offset from the horizontal plane.

### BACKGROUND

Bridge dies couple one integrated circuit (IC) die to another IC die on an integrated circuit (IC) package. Some bridge dies are placed in deep cavities on the IC packages in order to embed the bridge die within dielectric layers of the packaging. Bridge dies such as embedded multi-die interconnect bridges (EMIBs) with through silicon vias (EMIB-Ts) have a bottom with electrical pads or contacts to couple to a metallization pattern, such as a conductive redistribution layer (RDL) connected to the bottom of the cavity.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a cross-sectional schematic diagram of an example integrated circuit (IC) package with two deep cavity embedded IC dies according to at least one of the implementations disclosed herein;

FIG. 2 is a close-up cross-sectional schematic diagram of the example IC package of FIG. 1 according to at least one of the implementations disclosed herein;

FIG. 3 is a method of manufacturing an IC package according to at least one of the implementations disclosed herein;

FIG. 4-6 are cross-sectional schematic diagrams for IC package manufacturing stages of the IC package of FIG. 1 according to at least one of the implementations disclosed herein;

FIGS. 7-9 are cross-sectional schematic diagrams of detailed IC package manufacturing stages of the IC package of FIG. 1 according to at least one of the implementations disclosed herein;

FIGS. 10 is a cross-sectional schematic diagrams of an IC package manufacturing stage of a first alternative of the IC package of FIG. 1 with different types of die according to at least one of the implementations disclosed herein;

FIG. 11 is a cross-sectional schematic diagrams of an IC package manufacturing stage of a second alternative of the IC package of FIG. 1 with an underfill guard rail according to at least one of the implementations disclosed herein;

FIGS. 12-16 are cross-sectional schematic diagrams of IC package manufacturing stages of a third alternative of the IC package of FIG. 1 with hybrid bonding according to at least one of the implementations disclosed herein;

FIG. 17 is another method of manufacturing an IC package according to at least one of the implementations disclosed herein;

FIGS. 18-20 are cross-sectional schematic diagrams of example IC package manufacturing stages for the manufacturing method of FIG. 17 according to at least one of the implementations disclosed herein;

FIG. 21 is a top view of the IC package formed by the method OF FIG. 17 according to at least one of the implementations disclosed herein;

FIG. 22 is yet another method of manufacturing an IC package according to at least one of the implementations disclosed herein;

FIGS. 23-25 are cross-sectional schematic diagrams of example IC package manufacturing stages for the manufacturing method of FIG. 22 according to at least one of the implementations disclosed herein;

FIG. 26 is a cross-sectional schematic diagram of an example IC package with a fiducial according to at least one of the implementations disclosed herein;

FIG. 27 is a top view of the fiducial of the IC package of FIG. 26 according to at least one of the implementations disclosed herein;

FIGS. 28-31 are cross-sectional schematic diagrams of IC package manufacturing stages of the IC package of FIG. 26 according to at least one of the implementations disclosed herein;

FIG. 32 is a functional block diagram of an electronic computing device including an IC package with a deep cavity IC die in accordance with various implementations herein; and

FIG. 33 is a schematic diagram of a mobile computing platform and a data server machine employing an IC package with a deep cavity IC die in accordance with various implementations.

### DETAILED DESCRIPTION

Implementations discussed herein variously describe assembly of electronic packages with deep cavity arrangements for embedded dies, where a significant increase in the efficiency of the assembly is achieved by using an excimer laser to form the deep cavity and directly uncover metallization in the cavity, thereby omitting many operations previously used to protect the metallization during drilling. The order of the operations also may provide more efficiency by performing the cavity drilling before placing and/or patterning metallization at the bottom of the cavity. Also, fiducials disclosed herein provide higher accuracy alignment of lithography, laser, drilling, and/or die attachment at the deep cavity as well. These deep cavity arrangements are in accordance with various implementations.

The technologies described herein may be implemented in one or more electronic devices. Non-limiting examples of electronic devices that may utilize the technologies described herein include any kind of mobile device and/or stationary device. such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including integrated circuit architecture with integrated circuit packaging large cavity architecture as described herein.

Implementations are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein. Axes on the figures show the orientation of cross-sections, and the axes of a first assembly stage in a sequence of stages applies to all of the stages unless described otherwise.

It also should be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that implementations may be practiced without these specific details. In some instances, well-known methods and devices are shown in block diagram form, rather than in detail, to avoid obscuring the implementations.

Reference throughout this specification to “an implementation” or “one implementation” or “some implementations” means that a particular feature, structure, function, or characteristic described in connection with the implementation is included in at least one implementation. Thus, the appearances of the phrase “in an implementation” or “in one implementation” or “some implementations” in various places throughout this specification are not necessarily referring to the same implementation. Furthermore, the particular features, structures, functions, or characteristics may be combined in any suitable manner in one or more implementations. For example, a first implementation may be combined with a second implementation anywhere the particular features, structures, functions, or characteristics associated with each of the two implementations are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular implementations, “connected” may be used to indicate that two or more elements are in direct physical, optical, and/or electrical contact with each other. “Coupled” may be used to indicate that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Herein, the term “conductive feature” or “metal feature” may refer to any metal structure within a package that is part of the extra-chip circuitry, and is generally embedded within the dielectric material of the package. Structures include traces, caps, contacts, and pads that are within a metallization layer or plane (e.g., in-plane). Vias or pillars that form interconnects interconnecting in-plane conductive features within adjacent metallization levels are included as well. “Conductive features” may be substituted by “metal features” or just “features” at times within the disclosure.

Herein, the term “circuit” or “module” may refer to one or more passive and/or active components that are arranged to cooperate with one another to provide a desired function. The term “signal” may refer to at least one current signal, voltage signal, magnetic signal, or data/clock signal.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking, or in any other manner.

Also, chemical compounds without stoichiometry labels are not necessarily limited to 1:1 quantities. Thus, for example, “FeCo”, “FeNi”, “SnCuIn”, “NiWP” does not imply or limit the compound to a particular stoichiometry of those elements.

Deep cavity metallization and fiducial arrangements for embedded die and assembly thereof on integrated circuit packaging is described herein.

Redistribution layers (RDLs) at the bottom of deep cavities for bridge die have conductive metallization to transmit electrical signals and/or electrical power through the bottom of the bridge die. In these arrangements, the bridge die, or EMIB-T die (or just referred to as an EMIB-T) receive the signals and/or power, and/or provide the signals and power to additional dies coupled to each other through the EMIB-T.

The RDL may have Cu pads inside of the deep cavity to establish the electrical interconnects between the EMIB-T and substrate. The formation and protection of the Cu pads in the cavity to be in a condition to form interconnects with the EMIB-T is not a trivial task. A conventional laser, such as a CO2 laser, used for skiving a cavity for die embedment has a relatively large, uncontrolled range of varying ablation depth and ablation rate. This can cause too much variation to the depth of the cavity, which may impact amount of Cu pads and/or contacts revealed at the bottom of the cavity and impact bonding between cavity pads and pads on EMIB-T dies. Such CO2 drilling can result in uncontrolled depth variation of +/−10-20 microns and can cause undesired deep gouges making the dielectric layer unusable.

In this case, and while the Cu pads at the cavity bottom themselves will not be significantly damaged, it is most efficient to simply cover the entire bottom of the cavity, including the pads, to provide a laser stop layer or just laser stop, so that the CO2 or other conventional laser does not ablate the dielectric layers at the bottom of the cavity. The laser stop also may be a diffusion protection layer, or cover a diffusion layer over the Cu pads, to reduce the amount of heat reaching the CU pads, particularly if solder caps are provided on the Cu pads before the cavity is drilled. The combination of Cu pad and solder cap is susceptible to too much intermetallic compound (IMC) generation.

The deposition and subsequent removal of a laser stop, however, can involve a large number of fabrication operations, which drives up cost and increases the run-time for the fabrication. One conventional process for handling the laser stop uses lithography and involves the following operations: (1) form pads to remain at the bottom of the cavity by performing lithography plating of metallization on a dielectric layer on a substrate core, (2) deposit a separation layer on the pads by performing lithography plating of the separation layer of a different metal and over the pads to keep the outer laser stop layer separate from the pads so that later etching will not damage the pads, and (3) deposit the laser stop layer over the separation layer. Each plating process includes a series of lithography operations such as acid cleaning, dry film resist (DFR) and resist laminate deposition and patterning, pressing of the DFR, exposure, development, cleaning, plating, and resist strip to remove the resist. After cavity drilling, further lithography operations are performed including etching off the outer laser stop layer and the separation plate. The formation and etching operations include wet chemistry processes.

In addition to the disadvantages mentioned above, the etching will cause residue to stick on the surfaces of the pads, which can be challenging and expensive to remove. The residue should be removed since the residue can reduce the surface area of the connection on the interconnect between the pads and the IC die.

Also, the depth of the cavity and height of the vias usually cannot be adjusted once a dielectric film is laminated. The heights depend heavily on the thickness of the dielectric layer, which limits the flexibility of the metallization arrangements that can be used.

With regard to aligning an EMIB-T (i.e., “die mount”) for assembly into a substrate package cavity, it is very difficult to perform alignment and/or determine a true position error between the EMIB-T, substrate RDL, and silicon DIE connections because these entities must span across multiple patterned layers. This can be important since the die mounting is one of the processes that requires high accuracy between patterns on the die and pads in the cavity to provide an adequate, working end product.

One approach simply aligns the die with the RDL at the bottom of the cavity. This, however, may result in significant alignment error as each subsequent layer above the cavity RDL may continue the alignment error. This can cause a significant difference in alignment of the top most surface layer (above the cavity) from the initial cavity RDL layer, especially when each layer adds additional error. This cumulative error is absorbed into the true position error between EMIB-T and silicon die.

By yet another known approach, each dielectric layer forming a cavity and the area round the cavity can have fiducials formed by lithography, laser, or both, and that overlap from layer to layer in top view. Say a substrate has layers 1 to 4 with layer 1 being the highest and layer 4 being the lowest. The fabrication may prepare the pads inside a deep cavity at a layer 2 by using alignment fiducials at a lower layer 3. After building layers 1 and 2, fiducials on layer 2 may be used to align metallization outside of the cavity area. The cavity then may be drilled through layer 1. A die then may be mounted inside the cavity using fiducial on layer 1 as well.

Since the die mount and pad formation at the bottom of the cavity were built using different fiducials on different layers, this introduces an error in position as well. Also, and as with the use of the RDL itself as the alignment guide, each additional alignment layer can introduce a certain amount of error due to tool accuracy. Thus, here too, the use of many layers and components will accumulate layer to layer offsets and become a potential throttle for package size and performance, resulting in large process errors due to different types of mis-alignments and bad imaging.

To resolve a number of these issues, a method of manufacturing an IC package includes drilling and skiving the deep cavity with an excimer laser that has good ablation depth and ablation rate control. The dynamic depth control capability with an excimer laser, referred to herein as selective ablation rates or depth, enables drilling cavities to target depths with an expected accuracy and surface roughness, thereby eliminating or limiting the need for costly and time consuming laser stops.

Specifically, an excimer laser, short for “excited dimer laser,” is a type of laser that produces short, high-energy pulses of ultraviolet (UV) light. Excimer lasers use a gain medium composed of a mixture of noble gases, such as xenon (Xe), krypton (Kr), or argon (Ar), and a halogen gas, typically chlorine (Cl) or fluorine (F). The “excited dimer laser” refers to the excited state of the molecules in this mixture. In the gain medium, the noble gas atoms are in an excited state due to electrical discharge or other energy input. These excited noble gas atoms can then form temporary molecules (dimers) with halogen atoms, such as XeCl, KrF, or ArF. As these excimer molecules return to their ground state, they release energy in the form of high-energy ultraviolet photons (UV light) due to spontaneous emission. The specific wavelength of the emitted UV light depends on the choice of noble gas and halogen used in the mixture. The gain medium is placed within an optical cavity that includes mirrors at each end. One of these mirrors is partially reflective, allowing a small fraction of the emitted UV light to pass through, while the rest is reflected back into the gain medium. This creates a resonant cavity where the light bounces back and forth, stimulating more emission and amplification. Excimer lasers generate extremely short pulses of UV light, typically in the nanosecond (billionth of a second) or even femtosecond (quadrillionth of a second) range. The short pulse duration is a result of the rapid de-excitation of the excited excimer molecules.

With regard to packaging substrate assembly, an excimer laser has selective ablation depth or laser absorption rates. In other words, the ablation or drilling depth of the excimer laser predictably changes within a wide range of depths depending on the material being drilled. Thus, a metal, such as copper, that can reflect much of incident light, dissipate significant amounts of heat faster and has a higher melting point may only be ablated a negligible amount (such as less than one micron), if any, whereas a dielectric, such as a build-up film dielectric material layer, may be ablated down 15 microns, when desired, and set to a depth to do so. The depth of the excimer ablation can be controlled by setting a number of laser pulses to be used. This is advantageous when the excimer laser can be used to drill a deep cavity for die embedment on a package substrate. A metallization pattern already embedded before the cavity is drilled can be uncovered by the excimer laser without significant reduction in the height to, or significant damage of, the metallization pattern while the laser removes surrounding dielectric material to form the bottom of the deep cavity. This all may be performed without the need for protective laser stop layers covering the metallization pattern.

The use of the excimer with its greater control of ablation depth and dielectric selective abrasion enables a wider range of EMIB-T structures including more cost effective fine-pitch solutions in the cavity. Since this a dry approach, it is much faster (better run rate) than the wet laser stop techniques by eliminating at least eight pre-drilling operations and two post-drilling operations related to the laser stop, thereby showing great potential of creating and scaling features as needed for next generation products.

The use of the excimer laser and EMIB-T also permits flexibility to enable certain alternative substrate arrangements. Thus, for example, embedded dies of different types may be on a single package substrate, such as both an EMIB and an EMIB-T, each in their own cavity.

Also, a barrier may be placed at the level of the RDL and around the RDL or other metallization pattern under the embedded IC die and near the IC die periphery. The barrier may be used to limit lateral spreading of encapsulant or underfill such as non-conductive film (NCF) and mold underfill technologies, and so forth, from between the IC die and the dielectric layer below the IC die.

By yet another option, the pads or other conductive features at the bottom of the embedded die and the conductive features or pads in the cavity may be connected by hybrid bonding. The pads in both the cavity and on the die may be within direct bondable film flash layers that are around the pads to enable a better supported, direct Cu to Cu bonding interface for potential fine-pitch interconnects, z-height reduction, and Imax improvement.

The completed package substrate with die embedded in cavities drilled by the excimer laser will have distinct characteristics at cross-sections of the substrate and under the embedded die that reveals the cavity drilling was performed by an excimer laser. Specifically, the cavity bottom pads below the IC die and solder have bottom surfaces that engage the dielectric layer below them and form a horizontal plane at the engagement or junction between the pads and the lower dielectric layer (or dielectric material layer). This same plane is the boundary between the lower dielectric layer and an adjacent next higher dielectric layer outside of the horizontal periphery of the IC die.

When an excimer laser is used, the upwardly facing surface of the lower dielectric layer (and that faces the IC die and underfill), will be offset from the horizontal plane (either higher or lower) since it was formed directly by the laser. The surface between two pads also is likely to be uneven, often having a middle portion at a different height or offset than the portions proximal to the pads. In contrast, if another laser is used that requires a laser stop in the cavity, the laser stop will be removed by etching after the cavity is drilled, and the etching will not significantly change the dielectric surface of the lower dielectric material layer, which will be maintained relatively smooth along the horizontal plane.

By yet other solutions, the order of the cavity drilling operations may be changed to drill the cavity before plating the metallization pattern or RDL on the bottom of the cavity. Once the cavity is drilled, a drill then can be used to drill via holes in the bottom of the cavity and to expose interconnect metallization below the cavity, when present, for interconnection to the RDL. With this arrangement, better bonding between pads in the cavity and the die is expected since the pads will be much cleaner since no etching or dielectric residue will be present on the pads before die bonding. The better bonding, in turn, may reduce package size, increase data bandwidth, and boost product performance.

This proposal also gives flexibility on depth of cavities and vias at the bottom of the cavity. Usually, the height of the cavity and vias is controlled by the thicknesses of the stacked dielectric layers, but now the cavity and via heights can be adjusted by using the excimer laser as and to a desire height since the drilling of the vias and plating of the vias and pads at the bottom of the cavity comes after the drilling of the cavity.

It should be noted for this option, the laser forming the deep cavity is not necessarily an excimer laser, and the laser ablating the via holes does not need to be the same laser forming the deep cavity.

By yet another solution using the earlier cavity drilling operations, a metal blanket layer is embedded within the stack of dielectric layers at the level of the bottom of the cavity to be used to form the RDL or metallization pattern after the cavity is drilled. Thus, in this case, the full stack of dielectric layers are created as with the option above. Rather than drilling via holes after the cavity is drilled, here the embedded blanket layer first may be used as a laser stop to protect the dielectric material underneath the cavity from being damaged. After cavity drilling, the laser stop itself is etched to form the RDL metallization pads at the bottom of the cavity. As a second advantage, while the metal blanket layer acts as protection, subsequent etching may be used to remove excessive metal on the blanket layer to form the pads. Thus, this process omits the wet chemical and other lithography operations that would have been used to create the RDL or metallization pattern at the bottom of the cavity.

Regarding alignment error reduction, by one solution the same fiducial pattern on the upper-most dielectric layer can be used to reduce lithography pad plating, laser drilling, and/or die mount alignment errors. In this case, an upper fiducial or fiducial pattern is only on the upper-most dielectric layer in a stack of the layers to be used to form a deep cavity for die embedment. Thus, the fiducial pattern is in proximity to the cavity area but also may be used to position metallization of other layers outside of the cavity. By one form, the fiducial pattern includes two circular grooves that may be formed by laser and two metal rings or members that may be formed by lithography, and both are positioned near opposite diagonal corners of the cavity area.

This fiducial arrangement greatly increases accuracy by eliminating or reducing the multi-layer fiducials, and by using the earlier cavity drilling processes mentioned above. Specifically, the metallization of at least one layer below the cavity bottom will be plated using other fiducials that are used to plate the rest of that dielectric layer and does not need to be in the vicinity of the cavity. Once the higher dielectric layers are deposited that will be used to form the deep cavity, the upper fiducial or fiducial pattern at the upper-most dielectric layer is all that is needed rather than fiducials on the other multiple layers. The upper fiducial can be used to align a drill to drill the cavity and then to align a drill with the buried metallization under the cavity bottom in order to drill via holes at the cavity bottom and to that buried metallization. The upper fiducial then can be used to perform the plating for the metallization pattern or RDL at the bottom of the cavity, and then can be used when the cavity is ready for die mounting.

By yet another fiducial option, a deep fiducial may be placed on the same level with, or part of, a metallization layer or metallization pattern forming the RDL and at the bottom of the cavity. Particularly, a deep fiducial skiving technique may be used to align layers above the cavity RDL to the RDL cavity pattern.

By one example form, the deep fiducial is a circular or curvilinear pad with a through-hole to generally form a doughnut shape. The laser may be used to clear a hole through a keep out zone above the fiducial and to form a hole under the fiducial and under the through-hole to make a continuous hole with the through-hole. This permits an understanding of the position of the metallization layer through the use of the deep down (multiple layers) fiducial o enable direct alignment to a “deep layer”. Once the cavity is drilled, the hole to the deep fiducial and cavity may be combined so that the deep fiducial is within the cavity before being embedded next to an attached die.

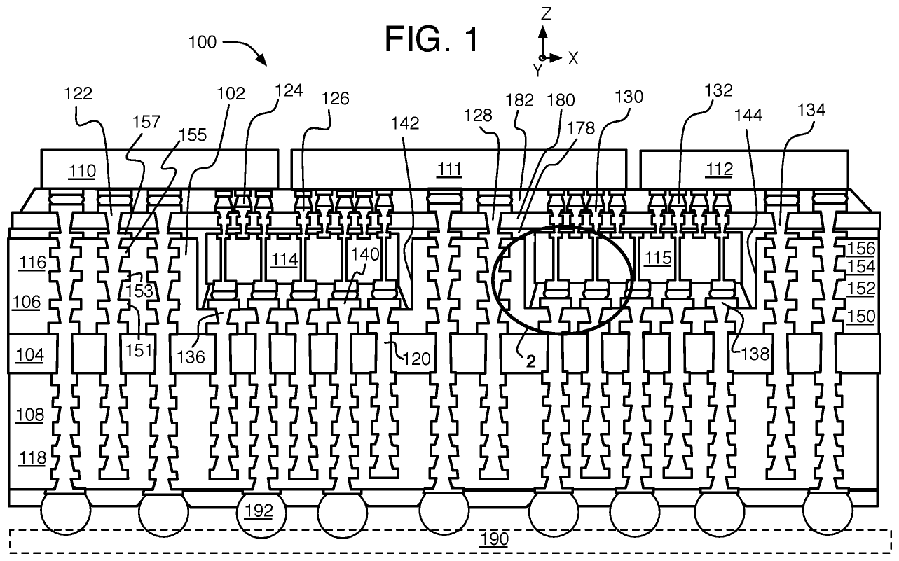

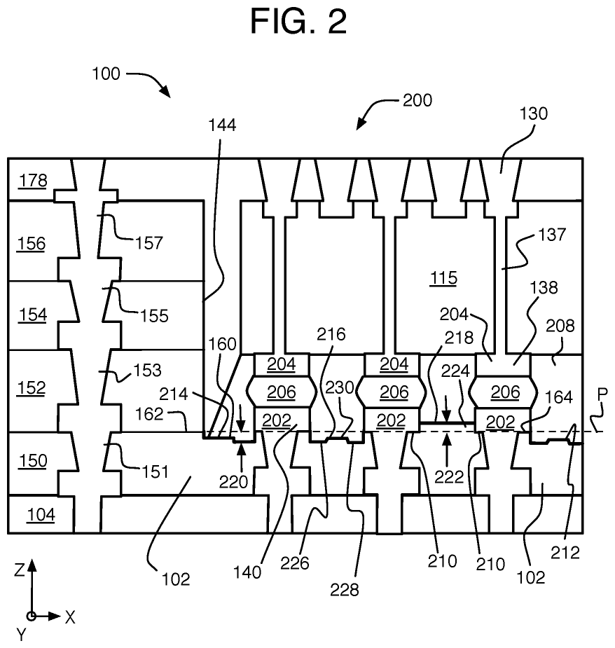

Referring now to FIGS. 1-2, an IC package 100 has a package substrate 102 with a substrate base (or core) 104 that divides the substrate 102 into a first or frontside 106 and a second (or reverse or back) side 108. The backside 108 may have interconnects to mount the IC package 100 on a board 190, such as a mother board, host board, and/or printed circuit board (PCB), and by one example, by second level interconnects (SLIs) 192. While the SLIs 192 are shown as solder balls, it is to be appreciated that the SLIs 192 may be any suitable interconnect architecture, including sockets or the like.

The frontside 102 has a double die bridge arrangement where chips or dies including a left die 110 is spaced laterally, in this example, from a middle die 111 which are coupled to each other through a bridge die 114 embedded in dielectric 116. The middle die 111 also is spaced laterally from a right die 112, and which are coupled to each other through a bridge die 115 also embedded in dielectric 116 on the frontside 106. By one form, the dies 114 and 115 are below an upper-most dielectric material layer 156 or at least below an upper-most metallization layer 157. This may include the die 114 or 115 being completely below those layers 156 and 157, or extending at least partially below those layers. In this example, the upper dies 110, 111, and 112 are located above the dielectric 116. By the example form herein, the bridge die 114 electrically and/or physically couples the left die 110 to the middle die 111, and the bridge die 115 couples the middle die 111 to the right die 112.

It will be understood that the term die refers to an integrated circuit (IC) component or chip, typically singulated from a wafer, that has one or more transistors and/or supporting circuitry to route electrical signals to the transistors, as well as any other IC components. Also, the dies 110, 111, 112, 114, and/or 115 may be monolithic dies, EMIBs as long as the EMIB has metallization on the bottom of the die, or EMIB-Ts, chiplets as explained below, or any combination of these, and alternatively, any of the upper dies 110, 111, and/or 112 may be bridge dies as well. Many variations are contemplated. By yet other approaches, the die 114 or 115 may not be in a bridge arrangement as long as it can be partially embedded in the dielectric 116 and has bottom metallization to couple to metallization in the bottom of a deep cavity.

As to when one of the dies is one or more chiplets, the IC industry is continually striving to produce higher computational performance in smaller packages for use in various electronic products, such as computer servers, portable computers, electronic tablets, desktop computers, and mobile communication handsets. High performance computing products often now include one or more microelectronic packages that contain various combinations of semiconductor tiles, chips, chiplets, and dies that are integrated into one functional unit. These composite, or heterogeneous, IC device structures may include tiles, chips, chiplets, or dies created using diverse technologies and materials. The tiles, chips, chiplets, or dies may be stacked vertically, placed horizontally, or both. Connections between different devices may employ a variety of technologies, including direct bonding. Chiplets, rather than monolithic dies, disaggregate the circuits. Thus, the IC Package 100 may have multiple chiplets including multiple bridges where just two of the bridges are being shown here. The chiplet 114 or 115 in this case, may be communicatively coupled by interconnects (or bridge interconnects) to other dies 110, 111, and 112 thereby itself forming an interconnect bridge between the dies 110 and 111 or 111 and 112. Also as mentioned, dies 110, 111, and 112 also can be chiplets. By one form, however, the dies 110, 111, and 112 are monolithic IC dies.

The term “chiplet” is used herein to refer to a die that is part of IC package 100 with dies 110, 111, and 112, and here forming a complete IC in terms of application and/or functionality, such as a memory chip, microprocessor, microcontroller, commodity IC (e.g., chip used for repetitive processing routines, simple tasks, application specific IC, etc.), and system-on-a-chip (SoC). In other words, by one example form, chiplet 114 or 115 is an individual die (or IC die) that can be connected together to other chiplets to create the functionalities of a monolithic IC. By using separate chiplets, each individual chiplet can be arranged and manufactured optimally for a particular functionality. In this case, dies 110, 111, and 112 could be chiplets as well. For example, a processor core that contains logic circuits might aim for performance, and thus might require a very speed-optimized layout. This has different manufacturing requirements compared to a USB controller, which is built to meet certain USB standards, rather than for processing speed. Thus, by having different parts of the overall arrangement separated into different chiplets, each one optimized in terms of design and manufacturing, the overall yield and cost of the combined chiplet solution may be improved.

The connectivity between these chiplets (or a chiplet and monolithic IC dies) may be achievable by many different ways. For example, in 2.5D packaging solutions, a silicon interposer and through silicon vias (TSVs) connect dies at silicon interconnect speed in a minimal footprint. In another example as described herein, EMIBs or EMIB-Ts have a silicon bridge or bridge die 114 or 115 embedded under the edges of two interconnecting dies 110 and 111 or 111 and 112, and facilitates electrical coupling between them. In a three-dimensional (3D) architecture, the chiplets are stacked one above the other, creating a smaller footprint overall, and could form one multi-layer bridge. Typically, the electrical connectivity and mechanical coupling in such 3D architecture is achieved using TSVs and fine pitch solder-based bumps (e.g., C2 interconnections could be used). The EMIB or EMIB-T and the 3D stacked architecture also may be combined using an omni-directional interconnect (ODI), which allows for top-packaged chips to communicate with other chips horizontally using EMIB or EMIB-T and vertically, using through mold vias (TMVs) which are typically larger than TSVs.

In some implementations that use chiplets, a composite chip may have a fill dielectric layer over back-end-of line (BEOL) metallization stack. A fill dielectric layer near the chiplet or bridge die here (in addition to the main or bulk dielectric 116), may fully surround chiplet sidewalls, embedding a chiplet within dielectric material, and may be the dielectric or may be a separately molded dielectric abutting dielectric 116. A fill dielectric may stabilize and strengthen the package 100, and/or provide a platform for higher BEOL metallization layers. In some implementations, a fill dielectric layer for a chiplet comprises an inorganic dielectric material, such as, but not limited to, amorphous and polycrystalline silicon oxides, in some cases having a higher k than inter-layer dielectric (ILD) materials. In some other implementations with chiplets, a fill dielectric layer comprises an organic material, such as, but not limited to, epoxy resins and epoxy resin composites.

Returning to the details of substrate 102, the substrate base or core 104 may be a base structure or layer itself that may be formed of one or more dielectric layers including glass, metal layers, or a combination of both. A stacking direction is outward from the base layer 104 and opposite on the two sides 106 and 108. The substrate base 104 may be referred to as a substrate core herein.

The package substrate 102 may comprise a plurality of laminated dielectric layers with conductive metallization or metallization layers embedded therein. In the specific example implementations here, the package substrate 100 may be fabricated in a build-up process (e.g., a bumpless dielectric material layer (BBUL) package), whereby the package substrate 102 is formed by build-up of individual levels where each level is referred to as a build-up or dielectric material layer and may have a dielectric film and a metallization plane or layer integral (or in other words, embedded within or on) with the dielectric film. In this example, and relevant here, frontside dielectric 116 has dielectric material layers 150, 152, 154, and 156 respectively with metallization layers 151, 153, 155, and 157. Going forward, the dielectric material layers may be referred to as just dielectric layers herein. The backside dielectric 118 may have dielectric layers as well. By the examples, herein, the dielectric layers are formed of dielectric build-up films for example. The dielectric 116 materials, as mentioned with the chiplets, may comprise organic material, such as, but not limited to, polymers, epoxy resins and epoxy resin composites, ceramics, and so forth, which may be a mold or mold layers, of mold resin, such as a polymer resin with insert fillers. By other forms, the dielectric 116 may be inorganic dielectric material, such as, but not limited to, amorphous and polycrystalline silicon oxides, in some cases having a higher k than inter-layer dielectric (ILD) materials. The package substrate 102 also may comprise glass layers, or any other materials typical of electronic packaging architectures. The dielectric 116 may embed or cover all of the dies 110, 111, 112, 114, and 115 when desired rather than just the bridge die 114 and 115.

Metallization 120 may include metallization planes and vertical interconnects with vias, and/or pillars throughout the dielectric layers on the substrate 100 including metallization extending through the substrate core 104 and within the dielectric layers of the dielectric 116 and 118 on the front and backs sides 106 and 108 including the metallization layers 151, 153, 155, and 157. Thus, the metallization may include traces, contacts, pads, caps, pillars, and vias, for example, and including interconnect vias. The metallization, and by one form all of the metallization and conductive features, may be formed of copper, or an alloy of copper. By other forms, some or all metallization may be formed of other conductive materials, other metals, or metal alloys. Otherwise, the arrangement of the patterns of the metallization 120 on the substrate 102 are not particularly limited except to provide a metallization layer with a metallization pattern, that may be an RDL, at the bottom of a deep cavity and for coupling to the bottom of at least one of the embedded dies 114 or 115.

The metallization 120 may comprise conductive features fabricated from electrodeposited copper (a semi-additive process (SAP)) and/or etched (a subtractive process) through a lithographically defined photoresist mask. New layers may be added to both sides by the build-up package in cycles of dielectric film lamination and formation of a new metallization plane over the laminated dielectric film as described below.

As to the example bridge arrangement on substrate 100, and by one form, each die 110, 111, and 112 has its own array of core interconnects 122 on the left, 128 in the middle, and 134 on the right respectively. The core interconnects 122, 128, and 134 may have one or more metal or conductive features including one or more vias, pillars, caps, bumps, pads, and so forth, and whether the interconnects terminate in the front dielectric 116 or pass through the substrate core 104 for coupling to the board 190. In either case, such core interconnects may be provided for interconnection to another IC component such as a die, chip, device, board, substrate, or other such IC components in or on substrate 102. The core interconnects may be considered part of metallization 120. The interconnects 122, 128, and 134 may have any desired arrangement of conductive features mentioned herein and are not particularly limited as with the other parts of metallization 120.

The bridge die 114, whether or not a chiplet, EMIB-T, or other die, may communicatively couple the left die 110 to the middle die 111 by using bridge interconnects (or bridge vias) 124 from the top of the bridge die 114 to the left die 110 and bridge interconnects 126 from the top of the bridge die 114 to the middle die 111. Likewise, the bridge die 115, whether or not a chiplet, EMIB-T, or other die, may communicatively couple the middle die 111 to the right die 112 by using bridge interconnects (or bridge vias) 130 from the top of the bridge die 115 to the middle die 111 and bridge interconnects 132 from the top of the bridge die 115 to the right die 112.

Cavity metallization (or RDL) interconnects (or just cavity or cavity bottom interconnects) 136 for a cavity 142 and cavity interconnects 138 for cavity 144 may extend from the dies 114 or 115, respectively, and to the bumps 192 or simply to within dielectric 118. Other details of the cavity interconnect coupling to the bridge die is provided below with FIG. 2. The term cavity interconnect is simply used to differentiate with the bridge interconnects at the top of the dies.

The die 114 and 115 may be encapsulated in an encapsulation or embedment layer 178. The encapsulation layer 178 may be lamination material such as build-up dielectric material and may be the same material as the dielectric layers 150 to 156. In this case, sidewalls of the cavities 142 and 144 may or may not be visible. Otherwise, the encapsulation layer 178 may be formed of mold resin that acts as an underfill, where the underfills are explained below with FIG. 2. A solder resist layer 180 above the dielectric or encapsulation layer 178 and an upper underfill 182 above the solder resist layer 180 may complete the package substrate 102. By one form, the solder resist 180 can be a mixture of epoxy and acrylic components, and normally has fillers such as Silica to improve its mechanical properties. The solder resist 180 can have a thickness that can vary from 5 microns to 30 microns, by one example.

Referring to FIG. 2, a close-up is shown of a cavity area 200 with die 115 and cavity 144, although die 114 and cavity 142 have the same or similar structure, and the following description applies to both dies unless mentioned otherwise. The die 115 may be an example EMIB-T with TSVs 137 extending through the height of the die 115 and that couples the upper bridge interconnects 130 to the lower cavity interconnects 138. The lower ends of the TSVs 137 may couple to conductive features, such as die contacts, caps, or pads 204, and so forth.

Metallization 120 on the lower dielectric layer 150 has a lower metallization layer 151 that couples to (or includes) metallization pattern 140, which may be an RDL, under the die 115. The metallization pattern 140 may include conductive features such as cavity caps or pads 202 on interconnects 138 and that are located at the bottom 160 of the cavity 144. Solder bumps 206 may couple the cavity pads 202 to the die pads 204 in the interconnects 138, and to provide electrical signals and/or power to metallization on the die 115 or to the dies 111 and/or 112 above the die 115. The RDL 140 may include, or couple to, multiple lower cavity interconnects 138, here being five in this example, and that may or may not all be axial with the upper bridge interconnects 130 and 132. In the example of package 100, any of the core, bridge, and/or cavity bottom interconnects shown may have other configurations than that shown with any desired arrangement of pillars, pillar ends, caps, pads, vias, traces, and any other conductive features.

The conductive features of the interconnects 122, 124. 126, 128, 130, 132, 136, and 138 may be formed of copper or other alloy or conductive material as mentioned above. The solder balls or bumps (or just solder) 206 as well as any other bumps herein may be formed of Sn, or may comprise Sn, such as with SnCu, or may comprise a compound with In such as SnIn or SnInCu, but otherwise may be any known solder that adequately forms connections on IC die and package substrates. As described below, one alternative omits the solder and uses hybrid bonding instead. The bridge interconnects 122, 124, 126, 128, 130, 132, 136, and 138 also may have one or more barrier layers, diffusion barrier layers, IMC barrier layers, or other types of layers.

An underfill 208 is positioned between the die 115 and the bottom 160 of the cavity 144 to support the die 115 and the solder or solder joints 206. A number of different underfills 208 may be used. By one form, a capillary action underfill (CUF) is used, and in this case, the remainder of the die 115 and above the upper-most dielectric layer 156 may be covered with additional lamination dielectric layers as the encapsulation layer 178 and that may be the same material as the dielectric layers 150 to 156. Alternatively, a pressurized mold resin may be used as both the mold underfill (MUF) and the encapsulation material 178. As another alternative, non-conductive film (NCF) underfill may be pre-laminated to the bottom of the dies 114 and 115 before singulation, and may be an epoxy or other material. As described for one of the alternatives below, when a package substrate has two or more embedded dies, each die may have a different underfill treatment when desired.

With regard to the use of the excimer laser and the bottom 160 of the cavity 144, the lower dielectric layer 150 and the next higher dielectric layer 152 define a horizontal plane P at the boundary or junction 162 between the two layers 150 and 152. When the pads 202 are plated or otherwise deposited or formed onto an upper surface 164 of the lower dielectric layer 150, the bottom or downwardly facing, surfaces 210 of the cavity bottom pads 202 are on the plane P, and this does not change even after the laser drilling.

The lower dielectric layer 150, however, has upwardly facing surfaces (or upper surfaces) 212, 214, 216, and 218 (thickened for emphasis) in this example, and that are between adjacent cavity pads 202. The excimer laser will roughen and otherwise ablate the dielectric between the original upper surface 164 and the now drilled surfaces 212, 214, 216, and 218. As shown, the ablation may extend deeper than the plane P, as shown by surfaces 212, 214, and 216, or may stop short, as shown by surface 218 where the surface is actually higher than the plane P such that a portion 224 of the next higher dielectric layer 152 was not ablated down to plane P. By another form, a single surface 216 between adjacent pads 220 also may have an uneven surface with steps, peaks, or recesses. For example, portions 226 and 228 of the surface 216 and that is adjacent the pads 202 are both higher or lower than a middle portion 230 of the surface 216. This may occur because there will be a variation in cavity depth with laser drilling due to processing capabilities of the laser and incoming film thickness variation which is not visible to the laser at the time of processing. By some forms, the resulting offset 220 or 222 of the surfaces 212, 214, 216, and/or 218 is at least 1 micron to clearly indicate the drilling was performed by an excimer laser (or other good ablation depth control laser) rather than being etched by lithography or any other alternative process to remove the dielectric material from the cavity 144.

Also, it will be appreciated that the structure of any of the implementations, herein, including bridge and cavity structure, may be provided on the backside instead of, or in addition to, the front side of the substrate core.

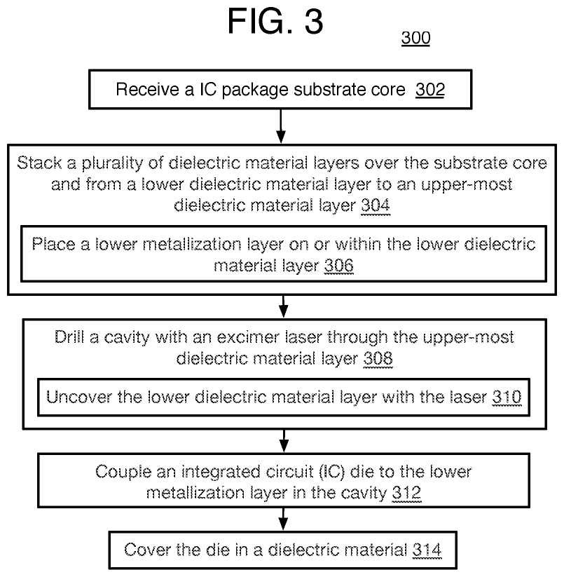

Referring to FIG. 3, an example process 300 of manufacturing an IC package is provided according to at least one of the implementations herein. Process 300 includes operations 302 to 314 generally numbered evenly, and electronic systems, devices, packages, and/or package substrates 100 of FIGS. 1-2 may be referred to herein where appropriate.

Process 300 may include “receive an IC package substrate core” 302, and that can support a stack of build-up or dielectric layers and metallization layers. Otherwise, the package substrate core is as described above with FIG. 1.

Process 300 may include “stack a plurality of dielectric material layers over the substrate core and from a lower dielectric material layer to an upper-most dielectric layer” 304. Here, dielectric layers may be stacked on the core including an upper-most dielectric layer where the laser will enter the stack to drill the cavity. By one form, four dielectric layers are present as in package substrate 102, but any number of dielectric layers may be used as needed. The dielectric layers may be stacked, by one example, by repeating cycles of dielectric layer deposition, laser drilling or etching of via holes, metal plating (such as copper plating) over the holes to form vias, and resist pattern and etching to form pads and/or traces over the vias.

This operation also includes “place a lower metallization layer on or within the lower dielectric material layer”, 306. The lower metallization layer may be or have a metallization pattern that can have many different arrangements, and may be an RDL that routes power into a die as described above. The metallization pattern may be located on the lower dielectric layer where a bottom of a cavity is to be formed,. The lower dielectric layer as well as the other dielectric layers may have dielectric material as described above, and metallization layers as described above with substrate 102. The metallization pattern may have conductive features such as caps, traces, or pads for coupling to the die, and may or may not be provided with solder caps before cavity drilling. The solder may be made of tin or other material mentioned above for example.

The process 300 may include “drill a cavity with an excimer laser through the upper-most dielectric material layer” 308. This includes using a laser with good ablation depth and rate control as described above. This operation also includes “uncover the lower dielectric material layer with the laser” 310. The excimer drill may be used to skive a deep cavity down to the metallization pattern pads (or other conductive features) at the bottom of the cavity. The skiving may be from left to right, layer by skiving layer, or some other motion. The metallization pattern pads at the bottom of the cavity may be slightly altered (ablated or melted) by the laser, but such alteration should be negligible. The drill may be set to use certain number of pulses, which may be determined by experimentation, to skive down to the upper surface of the lower dielectric layer and in turn, ideally the horizontal plane P, although the small offsets as described above with FIG. 2 should be the result. Other settings of the excimer laser include strength of pulse (fluence), repetition rate, focus offset and overlap ratio, which can be tuned collectively to obtain desired drilling performance.

The term ‘uncovering’ the lower dielectric layer includes the laser ablating into the lower dielectric layer as long as a new upper facing surface of the lower dielectric layer faces into the drilled cavity. This indicates that the drilling is performed without the need for a laser stop layer being plated over the metallization pattern, RDL, and the dielectric bottom of the cavity, thereby significantly reducing the number of operations to perform the cavity drilling and die mount.

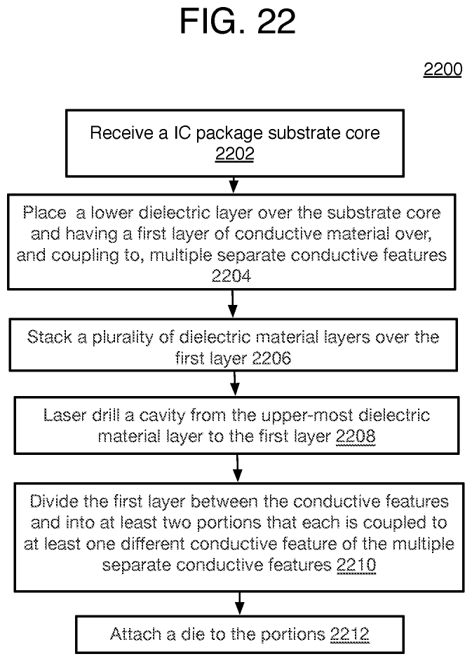

It should be noted that by an alternative form, the lower metallization layer is considered to be at a bottom of the lower dielectric layer, and the method comprises drilling via holes from the cavity bottom, through the lower dielectric layer, and to the lower metallization layer. The vias are then filled and pads formed on the cavity bottom to couple a die in the cavity to the lower metallization layer. Other details are provided below with FIGS. 22-25.

Process 300 may include “couple an integrated circuit (IC) die to the lower metallization layer in the cavity” 312, where a die, which may be a bridge die, an EMIB-T, a chiplet, or other type of die, may be attached to the metallization pattern through solder for example, although non-solder coupling may be performed as well. This operation also may include placing an underfill, such as by capillary action, mold resin, or NCF between the die and the metallization pattern and among the conductive features in the metallization pattern.

Process 300 may include “cover the die in a dielectric material” 314. The cavity then may be filled or at least partially filled with dielectric, which may be the same material as the dielectric layers and that encapsulates the die, but otherwise, solder resist, mold resin, or NCF, to name a few examples. Underfill may be placed under the die as well as described above. Once the cavity is filled and the die is encapsulated or embedded (or at least partially embedded), the package substrate is ready for stacking more layers and or mounting more dies on the substrate, such as mounting the dies for coupling to the top of the now embedded bridge die. It will be understood that when the die is shorter than the cavity height, the dielectric may completely embed the die, but when the die is tall and extends above the upper-most dielectric layer, dielectric material that may or may not be the same or similar material as the stacked dielectric layers disclosed here and may fill the spaces in the cavity between the die and the sidewalls of the cavity. Also in this case, another dielectric layer, which may or may not be the same material as the stacked dielectric layers, may be placed over the top of the die.

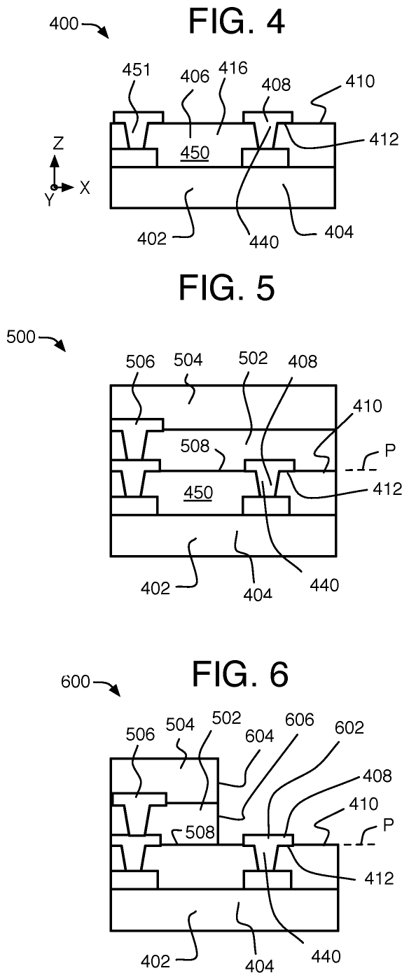

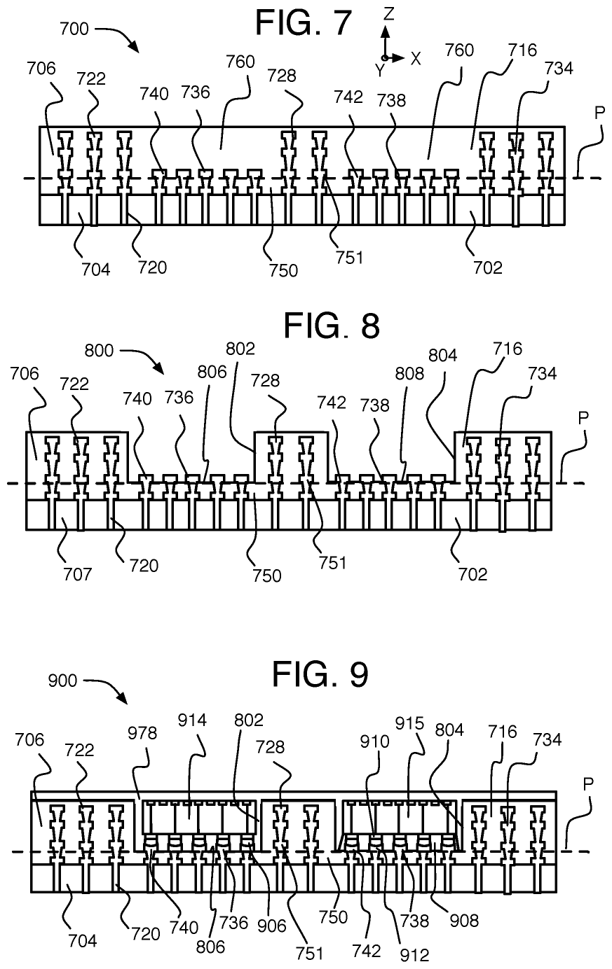

Referring to FIGS. 4-6 for more detail, a process for assembling an IC package is shown, and particularly for assembling an IC package substrate with an embedded die without the use of a laser stop to drill the cavity and mount the die, in accordance with at least one of the implementations herein. The process stages numbered 400 to 600 by multiples of 100 are shown in FIGS. 4-6 merely as one example process, and it will be appreciated that many different process flows may be used in order to provide such an embedded die interconnect layer as described herein. FIGS. 7-9 is a similar process to FIGS. 4-6 except with different details in stages 700-900.

Referring to FIG. 4, an IC package substrate intermediate manufacturing stage 400 shows a package substrate 402 with a substrate core 404, and a first or front side 406 with a dielectric 416 that has a lower dielectric layer 450 with a lower metallization layer 451. The lower metallization layer 451 may have a metallization pattern or RDL 440 that is to be placed at the bottom of a cavity and to be coupled to a die in the cavity. The metallization may be formed of copper or other materials as mentioned above, and may be plated by either a semi-adaptive process (SAP) that uses a seed layer that is later etched, or a subtractive process of etching. Thus, the metallization pattern (or RDL) 440, as well as other metallization such as caps, traces, or pads, is formed by using a resist, such as laminated dry film resist (DFR), and mask to shape the resist into a desired pattern. Copper plating is then used to form the metallization pattern (or RDL) 440 in the desired pattern. In this example, metallization pattern 440 has a pad 408 with a lower or bottom surface 412 that is at the upper surface 410 of the lower dielectric layer 450.

Referring to FIG. 5, and for a stage 500, the operations explained above for layer 450 may be repeated for each subsequent dielectric layers 502 and 504 shown here, which adds a metallization layer 506 to dielectric layer 502 and where layer 504 is an upper-most dielectric layer. As shown, the bottom surface 412 of the pad 408 is on the boundary or junction 508 between the layers 450 and 452, which defines horizontal plane P.

Referring to FIG. 6, a stage 600 shows a cavity 604 drilled with an excimer laser or other laser with good ablation rate and depth control. After the drilling, the cavity 604 is formed with a sidewall 606, which may be tapered although not shown, and the upper surface 410 now becomes the bottom dielectric surface of the cavity 604. Although it cannot be seen here, the surface 410 will be offset from horizontal plane P as shown in FIG. 2. The bottom 412 of the pad 408 will remain on the horizontal plane P and in contact with the lower dielectric layer 450.

It should be noted that the elements of the substrate are numbered similarly to that of FIG. 1 where possible, and where elements are already adequately described on package 100, the description is not repeated for any of the stages herein in FIGS. 4-25.

Referring to FIG. 7, an IC package substrate intermediate manufacturing stage 700 shows a package substrate 702 that is similar to package substrate 102 and 402, such that similar or the same components will not be described again. Here, the substrate 702 has all dielectric layers stacked up to an upper-most layer that is ready for laser drilling. Cavity keep out zones or areas 760 are maintained to keep metallization clear of the laser drilling, and metallization layers of the dielectric 716 surrounding the cavity areas. Also as shown, at least two cavity areas 760 are being arranged for two die mounts. Each cavity areas 760 has a lower metallization pattern or RDL 740 and 742 in position to be at the cavity bottom once it is drilled, and where the metallization pattern 740 and 742 aligns with the horizontal plane P as described above with FIG. 2 and FIGS. 4-6.

Referring to FIG. 8, in a stage 800, a laser drill is used with skiving to drill through dielectric 716, and the cavity drilling resulted in cavities 802 and 804 near each other. The cavity drilling may have been performed by using an excimer laser, or other laser as mentioned above, and without a laser stop or protection layer, thereby reducing the number of operations to mount a die. The metallization patterns 740 and 742 are in place at the bottom of the cavities 802 and 804 respectively to receive a die. As this point, the bottom surfaces 806 and 808 of the cavities now will have the characteristic offsets from the plane P as shown on FIG. 2.

Referring to FIG. 9, in a stage 900, dies 914 and 915, such as an EMIB-T, chiplet, bridge die, and so forth is shown here, and may be attached respectively to the metallization patterns 740 and 742 by coupling to the cavity interconnects 736 and 738. Specifically, the cavity pads or traces 912 couple to die conductive features 910 such as contacts, pads, caps, or traces, 914 or 915 by solder 906, which may be solder or lower bridge bumps. The solder 906 is described in detail above with FIG. 2. Here, a flux may be applied to remove oxide and clean the pad surfaces before the solder is put in place. The dies 914 and 915 are entirely, or at least partially, placed lower than the upper-most metallization layer (157 shown in FIG. 1) in the dielectric material 116, or here 716.

Once the dies 914 and 915 are placed and attached in the respective cavities 802 and 804, underfill 908 may be inserted if not already in place, and an encapsulation layer 978 may cover the dies 914 and 915, cavities 802, and 804, and the dielectric 716. While an encapsulation layer 978 may be the same for both dies 914 and 915, the two dies do not always need to have the same underfill treatment. A number of different variations may be used. So for this example, both dies 914 and 915 are EMIB-Ts that attach to RDLs 740 and 742. In the illustrated example, the die 914 may have no separate underfill, and the encapsulation layer 918 may be made of a mold resin material that can be used as an underfill. In this case, the mold resin is pressurized to fill the underfill area between the die 914 under the surface 806 of the dielectric 716 (or lower dielectric layer 150 or 450 (FIG. 1 or 4). On the die 915, a non-conductive film (NCF) may be pre-laminated on the bottom of the die 915 and is the underfill material. Once solder is in place, thermal compression bonding may be applied. Otherwise, a capillary action, or other type, underfill 908 may be placed between the die 915 and the surface 808. When NCF or capillary action underfill is used, the type of material for the encapsulation layer 978 is not particularly limited and may be build-up films as with the stacked layers, mold resin, solder resist, and so forth.

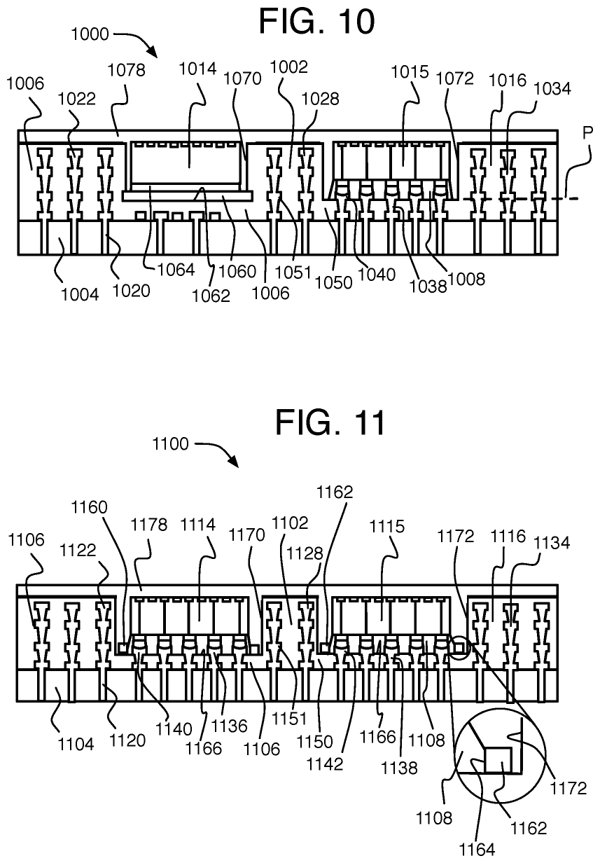

Referring to FIG. 10, an IC package substrate intermediate manufacturing stage 1000 shows a package substrate 1002 with a substrate core 1004, a first or front side 1006 with a dielectric 1016 that has a lower dielectric layer 1050. Other elements or components numbered similarly to that of substrate 102, 402, or 702 are not described again here. Stage 1000 shows an alternative arrangement to that of stages 700 to 900. Here, the die 1014 is an EMIB without metallization for an RDL below the die 1014, and may attach to bridge interconnects above the die 1014. The die 1015 remains an EMIB-T. In this case, the fabrication operations for the EMIB-T are the same and need not be explained again. For the EMIB 1014, a laser stop layer 1060, of a metal such as copper, may be plated on the upper surface 1062 of the lower dielectric layer 1050 at the level of the lower metallization layer 1051 as the metallization pattern 1040 is being formed for the EMIB-T 1015 as well. The dielectric layers are then stacked above the lower metallization layer 1051 as in the other implementations described herein already.

A cavity is then drilled for both dies 1014 and 1015, and the EMIB die cavity 1070 may or may not be drilled with the excimer laser drill, while the cavity 1072 for the EMIB-T is being drilled with the excimer laser drill. For the EMIB cavity 1070, the drilling may expose the laser stop 1060, but then the laser stop 1060 is kept in place since no electrical coupling needs to be provided to the die 1014 from the laser stop or below the laser stop 1060.

The die 1014 then may be attached, and may have a die backside film (DBF) 1064 with an adhesive material that is pressed against the laser stop 1060 to keep the die 1014 in place. The underfill of the die 1015 is as described above already. Thereafter, an encapsulation layer 1078 may be deposited, and the package substrate 1002 is ready for the subsequent operations to complete the package as already described. Substrate 1000 will have a completed package very similar to the substrate 1002 except for the EMIB 1014, laser stop 1060, and DBF layer 1064 and accompanying interconnects and cavity structure instead of that for the EMIB-T 114.

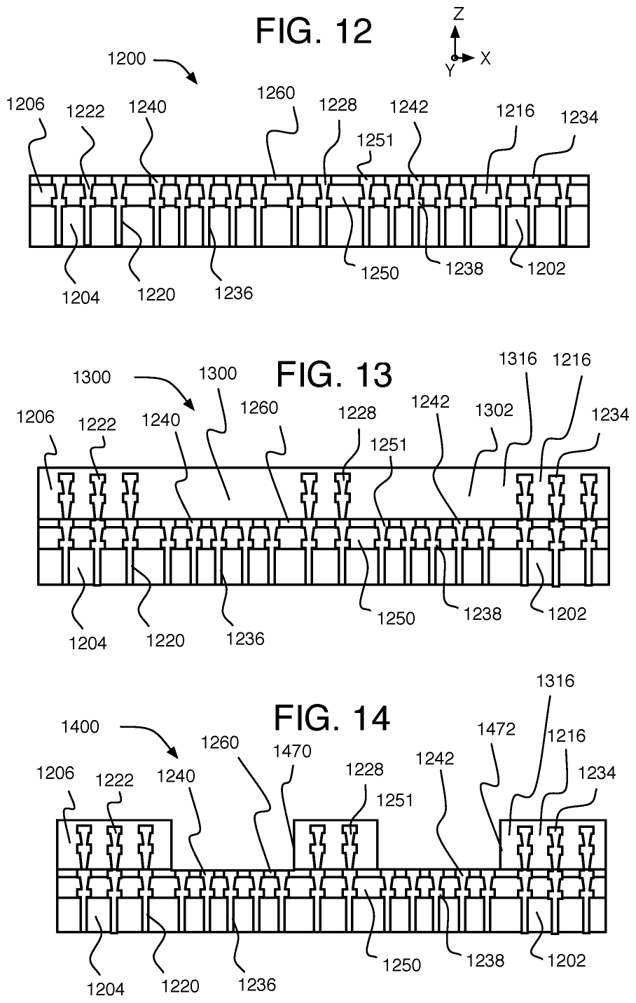

Referring to FIG. 11, an IC package substrate intermediate manufacturing stage 1100 shows a package substrate 1102 with a substrate core 1104, a first or front side 1106 with a dielectric 1116 that has a lower dielectric layer 1150. The layer 1150 may have a metallization layer 1151 with a metallization pattern or RDL 1140 or 1142 to respectively engage the bottom of dies 1114 and 1115. Other elements or components numbered similarly to that of substrate 102, 402, 702, or 1002 are not described again here.

Stage 1100 shows an alternative arrangement to stage 900, which is the same or similar except that both die may be EMIB-Ts and may or may not have the same underfill treatment. Also, here, a retaining members (or barrier) 1160 and 1162 may respectively encircle the dies 1114 and 1115, and particularly the metallization pattern 1140 or 1142 respectively. As shown on the close-up inset, an inner surface or wall 1164 of the retaining member 1162 engages underfill material 1108 spreading laterally outward to hold the underfill material 1108 in between the die 1015 and surface 1166 of the lower dielectric layer 1150. This may occur when NCF pre-laminated to the bottom of the die is compressed during solder bonding and expands laterally outward, for example. The member or barrier 1060 and 1062 may be formed of copper, and may be rectangular or any other convenient or efficient shape around the dies 1114 and 1115 and the metallization patterns 1140 and 1142. Otherwise, the operations are the same or similar to that of stages 700-900.

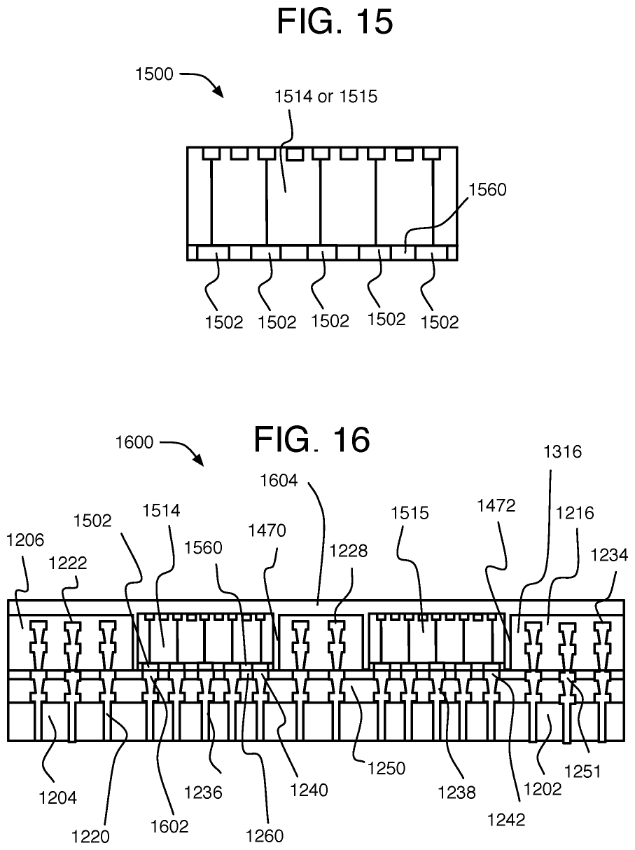

Referring to FIGS. 12-16, an IC package is shown, and particularly for assembling an IC package substrate with an embedded die without the use of a laser stop to drill the cavity and mount the die, in accordance with at least one of the implementations herein. In this alternative process, hybrid bonding is used. The process stages numbered 1200 to 1600 by multiples of 100 are shown in FIGS. 12-16 merely as one example process, and it will be appreciated that many different process flows may be used in order to provide such an embedded die interconnect layer as described herein. Those items numbered here that are similar to the numbering on FIGS. 1-11 may be the same or similar item previously described and need not be described again.

Referring to FIG. 12, in a stage 1200, a lower dielectric layer 1250 is deposited on a substrate core 1204 of a substrate 1202. A lower metallization layer 1251 is provided on the lower dielectric layer 1250. In this case, however, a direct bonding film (DBF) or film flash layer 1260 is patterned and laminated into the metallization layer 1251. Chemical mechanical polish (CMP) then may be performed to ensure the metallization, at least at the metallization pattern 1240 and 1242, is smooth and thickness variations are reduced. The DBF also acts as an adhesive layer in the final product. Such DBF may be a polymide for example.

Referring to FIG. 13, in a stage 1300, the remaining dielectric layers and metallization layers with interconnects (from left to right) 1222, 1236, 1228, 1238, and 1234 are stacked as shown and over the DBF 1260 to complete a dielectric 1316. A total front side dielectric 1216 includes the stack 1316, the DBF 1260, and the lower dielectric layer 1250 under the DBF 1260. The stacking also forms the cavity areas 1300 and 1302 free of metallization as describe with the other implementations herein.

Referring to FIG. 14, excimer laser drilling may be performed as described above in earlier implementations to form cavities 1470 and 1472 here. The excimer laser may vary the surface of the dielectric material 1260 facing upward and into the cavities, and as described with FIG. 2 here. The amount of height offset can be compensated by controlling the die DBF layer thickness combined with process optimization.

Referring to FIG. 15, in a stage 1500, a singulated die 1514 or 1515 for mounting is obtained, and may have a bottom die DBF layer 1560 between die conductive features 1502 such as die pads. The DBF 1560 may be of the same material as the DBF 1260.

Referring to FIG. 16, the dies 1514 and 1515 are placed in the cavities 1470 and 1472 and on the metallization pattern 1240 and 1242 respectively. More specifically, each die pad 1502 is placed directly on a pad 1602 of the metallization pattern 1240 or 1242. The dielectric adhesive on 1260 is placed directly against the dielectric adhesive on 1560 to promote die to cavity surface adhesion to Cu 1402 to Cu 1602 hybrid bonding joints through thermal compression bonding process. Embedded dies 1514 and 1515 are then encapsulated by layer of 1604 by lamination or molding process.

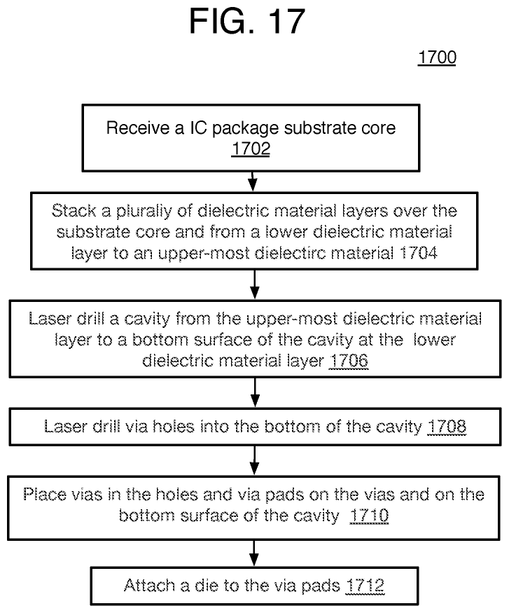

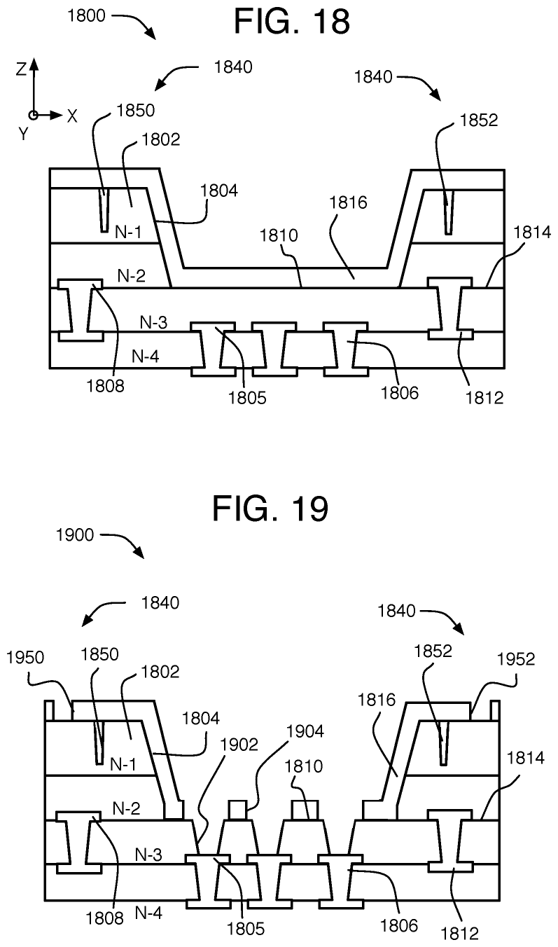

Referring to FIGS. 17-20, an example process 1700 of manufacturing an IC package is provided according to at least one of the implementations herein, and performs cavity drilling before forming a metallization pattern on the bottom of the cavity. Process 1700 includes operations 1702 to 1714 generally numbered evenly, and electronic systems, devices, packages, and/or package substrates 100 of FIGS. 1-2 may be referred to herein where appropriate. The process 1700 will be described with reference to manufacturing stages 1800 to 2000 of FIGS. 18-20 as well.

Process 1700 may include “receive an IC package substrate core” 1702, and as described with substrate 102 as one example.

Process 1700 may include “stack a plurality of dielectric material layers over the substrate core, and from a lower dielectric layer to an upper-most dielectric material layer” 1704. An example of the stacking of the layers also is as described on substrate 102, process 300, and other stages described above for other implementations.

Process 1700 may include “laser drill a cavity from the upper-most dielectric material layer to a bottom surface of the cavity at the lower dielectric material layer” 1706, and this may or may not be performed by an excimer laser. The excimer laser will make a level bottom of the cavity versus other lasers, such as a CO2 laser.

Process 1700 may include “laser drill via holes into the bottom of the cavity” 1708, and this may or may not be performed by the same type of laser that drilled the cavity. Referring to FIG. 18, a stage 1800 shows the cavity 1804 on an intermediate stage substrate 1802 that has already been drilled, and an operation is performed for locating the via holes in the bottom of the cavity 1804 in the first place. Particularly, substrate 1802 has a stack of dielectric layers from a lower dielectric layer N-4 to an upper-most dielectric layer N-1, and with a lower metallization layer 1806 within and on the lower dielectric layer N-4. The lower metallization layer 1806 has vias and pads aligned with the location of the cavity 1804 before the cavity 1804 is formed. The other dielectric layers also may have metallization or metallization layers, such as vias with pads outside of the cavity area. Specifically, the layer N-3 has a metallization layer 1808 and forms the bottom 1810 of the cavity 1804. The metallization layer 1808 will have the metallization pattern at the bottom 1810 of the cavity 1804 once it is formed. The layer N-3 also may have metallization 1812 outside of the cavity area and that is part of the metallization layer 1808. Such metallization 1808 may have caps plated on the upper surface 1814 of the layer N-3 and that was patterned by etching or SAP.

Once the cavity 1804 is drilled, a resist layer such as a dry film resist (DFR) 1816 may be deposited on the cavity 1804 and over the upper-most dielectric layer N-1. The DFR 1816 is then patterned by using a mask and lithography to create holes in the DFR 1816 which are the location of the vias and pads to be plated. The patterning forms pad holes 1904 as shown on FIG. 19.

Referring to FIG. 19, in a stage 1900, the vias holes are drilled and may be drilled by the excimer or other laser. It can be a different laser than that used to drill the cavity. As shown, via holes 1902 are drilled and uncover the metallization at lower metallization layer 1806.

Process 1700 then includes “place vias in the holes and via pads on the vias and on the bottom surface of the cavity” 1710. Referring to FIG. 20, a stage 2000 has metal for vias 2002 filled or plated in via holes 1902, and pads 2004 coupled to the vias 2002. The pads 2004 have a bottom or lower facing surface engaging the upper facing surface 1814 of the lower layer N-3. By one interpretation, the layer N-3 may be the lower dielectric layer with the metallization pads 1805, where the pads 1805 are on the layer N-3 as shown.

Process 1700 may include “attach a die to the via pads” 1712, and as shown in stage 2000, and as described above. With this arrangement, the pads 2004 in the cavity 1804 will have a different thickness than pads 2006 of the metallization 1812 outside of the cavity area but in the same metallization layer 1808 as the pads 2004. This difference in thickness is shown by the dimension t and is due to the cavity pads 2004 being formed by a different, separate patterned resist than that used for the plating of the pads 2006 before the cavity was formed. Different techniques may have been used as well such as SAP on the outside of the cavity area compared to etching within the cavity or vice-versa.

Referring to FIGS. 18-20 again, stages 1800 to 2000 also show fabrication of a fiducial pattern 1840. In this example, the fiducial pattern 1840 has grooves 1850 and 1852 into the upper-most dielectric layer N-1 as recessed fiducial marks, which may be circular or other shape in top view, formed by laser with one on each side of the cavity 1804. The grooves 1850 and 1852 may be formed in the same drilling operation as the cavity 1804. The groove 1850 is covered by the DRF 1816 (stage 1800), which is then patterned (stage 1900) with holes 1950 and 1952 by lithography, to form layers or members 2050 and 2052. The members (or raised fiducial features or marks) 2050 and 2052 may be metal and plated with the same lithography process for forming pads 2004 in the cavity 1804. Thus, by one form, no extra operations are performed to form the fiducial pattern 1840.

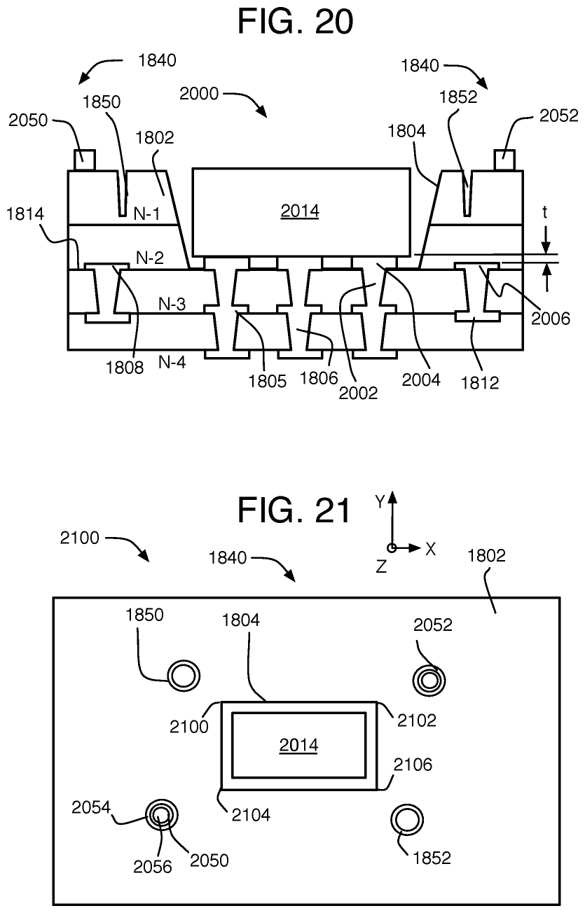

Referring to FIG. 21, the fiducial pattern 1840 has the grooves 1850 and 1852 near and outside of opposite corners 2100, 2106 of the cavity 1804, while the members 2050 and 2052 are respectively at the other opposite corners 2102, 2104 of the cavity 1804. In this example, the members 2050 and 2052 may have an outer annular portion 2054 around a middle pillar portion 2056. Both the grooves 1850 and 1852, and the members 2050 and 2052 may have outer diameters of 100-300 microns, such as for die 2014 at 4×10 mm in top view as one example.

By one approach, the fiducial pattern is only placed on the upper-most dielectric layer N-1 to avoid multi-layer fiducials that can cause alignment errors from the use of the different fiducials for die mount alignment. The lithography or SAP for the metallization 1806 under the cavity 1804 and metallization layer 1808 laterally outside of the cavity 1804 may be placed by using fiducials that are farther away from the cavity 1804 (and not shown here). Alignment for metallization 2002, 2004 at the bottom of the cavity 1804 may use both the fiducial grooves 1850 and the deeper metallization 1806 since the metallization 2002, 2004 at the bottom of the cavity 1804 is placed at the same time as the raised fiducials 2050. Both raised and groove fiducials then can be used for die mount.

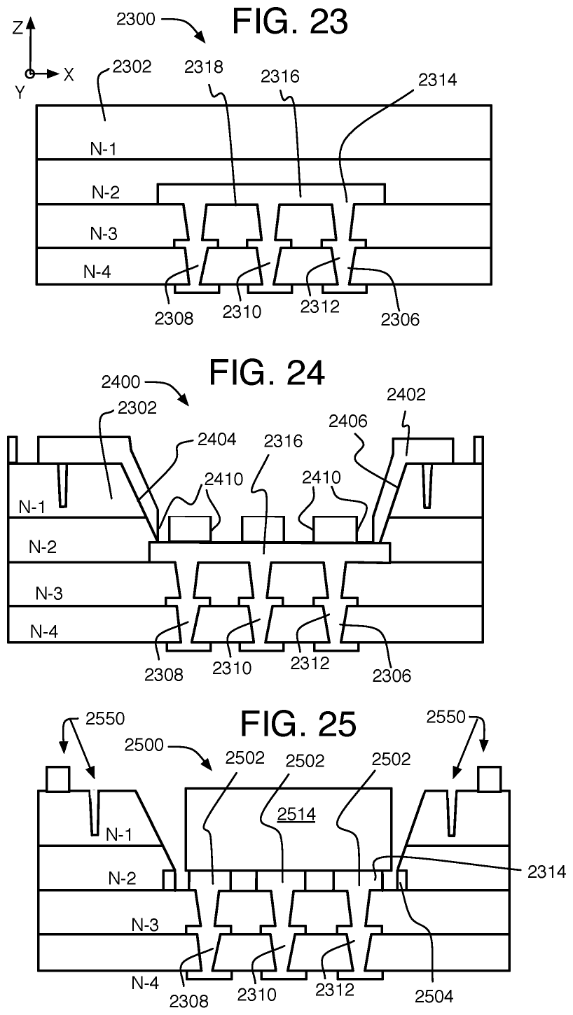

Referring to FIGS. 22-25, an example process 2200 of manufacturing an IC package is provided according to at least one of the implementations herein, and forms a metallization pattern at the bottom of a deep cavity after the cavity is formed. Process 2200 includes operations 2202 to 2212, generally numbered evenly, and electronic systems, devices, packages, and/or package substrates 100 of FIGS. 1-2 may be referred to herein where appropriate. The process 2200 will be described with reference to manufacturing stages 2300 to 2500 of FIGS. 23-25 as well.

Process 2200 may include “receive an IC package substrate core” 2202, and this is as described above with process 300 or 1700.

Process 2200 may include “place a lower dielectric layer over the substrate core and having a first layer of conductive material over, and coupling to, multiple separate conductive features” 2204, and this can be explained with stage 2300. Thus, the first layer may be a continuous or blanket layer of conductive metal, such as copper, and may extend over multiple vias, traces, or other separate, distinct conductive features that may be on separate interconnects for example. Once placed in the area for drilling a deep cavity, the first layer can act as a laser stop, and then can be divided to be multiple separate pads for the multiple vias or conductive features.

Referring to FIG. 23 for example, in a stage 2300, an IC package substrate intermediate manufacturing stage 2300 shows a package substrate 2302 with a bottom or lower-most dielectric layer N-4 that is deposited over a substrate core (not shown) and by methods explained above for build-up or dielectric layers that applies to any of the dielectric layers that cooperatively form a bulk or mass dielectric over a substrate core. Metallization layer 2306 is plated onto the dielectric layer N-4 whether by lithography and etching or by an SAP process. The metallization layer 2306 has vias and pads under the location of a future cavity and embedded die, and forming at least, and here, three interconnects 2308, 2310, and 2312.

Next, a lower dielectric layer N-3 is deposited on the layer N-4, and the process repeats to plate a lower metallization layer 2314 that includes a continuous or blanket (or first or laser stop) layer 2316 that extends over, and couples to, multiple interconnects and/or other conductive features under the blanket layer 2316. The interconnects 2308, 2310, and 2312 now extend upward through the dielectric layer N-3. in this stage, and the blanket layer 2316 extends over, and is coupled to, interconnects 2308, 2310, and 2312. The lower dielectric layer N-3 has an upper surface 2318 that is the target deep cavity bottom and the lower dielectric layer is plated on the surface 2318. The blanket layer 2316 may have outer dimensions that align with a bottom of a deep cavity to be drilled over the blanket layer 2316. By one form, the blanket layer is to cover the entire bottom of the planned cavity and may act as a laser stop. Thus, the blanket layer may have a width greater than 500 microns, and instead of connecting to the top of three interconnects, there may be at least one or many more than three.

Process 2200 may include “stack a plurality of dielectric material layers over the first layer” 2206, where the next dielectric layers N-2 and N-1 are stacked over the dielectric layer N-3 and the blanket layer 2316. The blanket layer 2316 is now embedded within the dielectric of the layer N-2 in this example.

Process 2200 may include “laser drill a cavity from the upper-most dielectric material layer to the first layer” 2208. Here, a laser is used to drill the cavity, and may or may not be an excimer laser drill since the blanket layer 2316 may act as a laser stop. A cavity 2404 is formed removing dielectric material and exposing the blanket layer 2316 within the cavity 2404 as shown in stage 2400 (FIG. 24).

Referring to FIG. 24, process 2200 may include “divide the first layer between the conductive features and into at least two portions that each is coupled to at least one different conductive feature of the multiple separate conductive features” 2210. In a stage 2400, this operation first includes depositing a resist layer 2402 such as a dry film resist (DFR) on the open cavity 2404 and over the upper-most dielectric layer N-1. Particularly, the resist 2402 is deposited on the cavity sidewalls 2406 and on the blanket layer 2316.

The resist 2402 is then patterned by using a mask and lithography to create holes 2410 in the resist 2402 and at the bottom of the cavity 2404, which are the locations of the blanket layer 2316 to be etched away so that the remaining parts of the blanket layer 2316 form a metallization pattern or RDL of pads 2502 (FIG. 25) on metallization layer 2314. The etching will also leave metal material or copper under an overhang 2504 (FIG. 25) at the sidewalls 2406 of the cavity 2404 where the etchant material will not be able to reach.

Referring to FIG. 25, process 2200 may include “attach a die to the portions” 2212. In a stage 2500, the pads 2502 were already plated as shown and the resist 2302 was stripped. A die 2514, such as an EMIB-T or other type of die, is then mounted on the pads 2502, and the substrate 2502 may be provided for the subsequent operations to complete the package, as described above with the other implementations herein. With this arrangement, the process to form and divide the blanket layer 2316 eliminates a significant amount of lithography fabrication operations that would have been used to form the metallization at a bottom of the deep cavity, and then form and remove a laser stop.

Stages 2300-2500 also may form a fiducial pattern 2550 that is the same as fiducial pattern 1850 (FIGS. 18-21), and formed in the same way, as described above with stages 1800-2000 such that the fiducial need not be described again here.

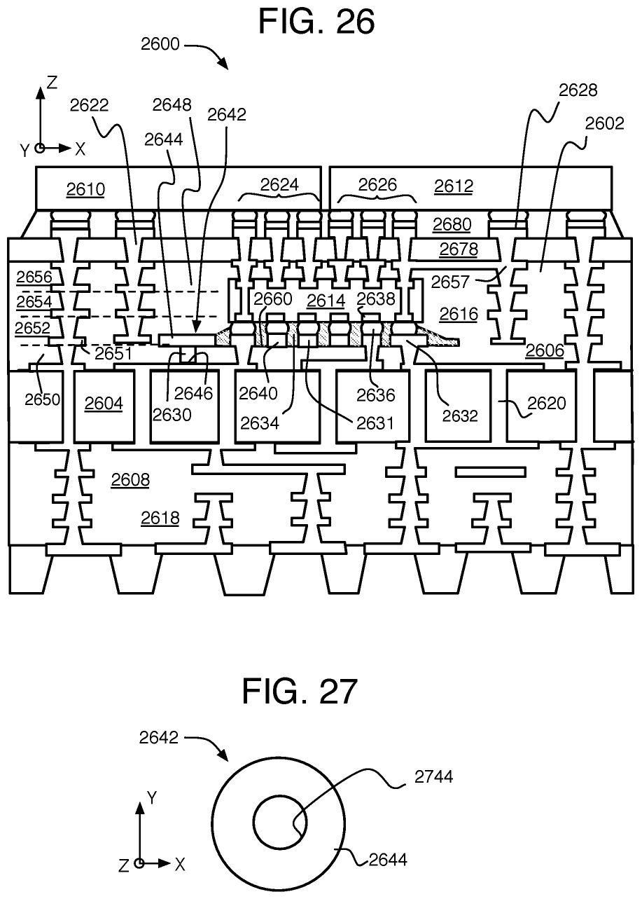

Referring to FIG. 26, an IC package 2600 has a package substrate 2602 with similar structure to that of substrate 102, such that the details of the basic structure need not be repeated here. The substrate 2602 has a substrate base (or core) 2604, a front side 2606 with dielectric 2616 and a backside 2608 with dielectric 2608. The backside may be coupled to a board or host as described with package 100. The substrate 2602 also has a bridge arrangement with a left die 2610, a right die 2612, and a bridge die 2614 that couples the left and right dies 2610 and 2612 to each other. The bridge die 2614 may be an EMIB-T, chiplet, or other die that couples to metallization 2640 on the bottom of the die 2614. By one form, the die 2614 is at least partially embedded below an upper-most dielectric layer 2656 or at least below an upper-most metallization layer 2657, as with die 114 on substrate 102.

The bridge arrangement also may have core (or non-bridge) interconnects 2622 and 2628 that respectively couple to the dies 2610 and 2612, and bridge interconnects 2624 that couple the bridge die 2614 to the left die 2610 and bridge interconnects 2626 that couple the bridge die 2614 to the right die 2612. The core interconnects and the die 2614 may be embedded within stacked dielectric layers 2650, 2652, 2654, and 2656 forming the dielectric 2616. The die 2614 also may be coupled to lower bridge interconnects (or cavity bottom interconnects) 2632 that include a metallization pattern, that may be an RDL, 2640 and that is part of a lower metallization layer 2651 of the lower dielectric layer 2650. The metallization pattern 2640 may have multiple pads 2631 or other conductive features coupled to die conductive features 2638, such as contacts, pads, or vias, on the die 2614. By one form, the pads 2631 and conductive features 2638 are coupled to each other through solder 2636. An underfill 2634 surrounds the interconnects 2632 between the die 2614 and an upper surface 2660 of the lower dielectric layer 2650. A protective or encapsulation layer 2678 such as solder resist or other materials mentioned herein may be placed over the dielectric 2616 and die 2614, while an upper underfill layer 2680 is placed under the dies 2610 and 2612, and over the encapsulation layer 2678. The materials and configurations for these layers and parts of the substrate 2602 are already explained above with substrate 102.

Relevant here, the lower metallization layer 2651 has a deep fiducial pattern 2642 that can be used for alignment during lithography, laser drilling, and/or die mount as well as other assembly operations. Such deep location provides direct alignment with a deep layer for more accurate alignment with that layer, and here for example alignment with the metallization pattern 2640 to couple to the bottom of the embedded die 2614. Alternatively, the fiducial pattern 2642 could be placed at many different layers rather than the lower metallization layer when desired, and could be more than one fiducial on one or more layers although that should be limited to avoid alignment errors. By the example form, the fiducial 2642 is spaced laterally of the die 2614 and may be in contact with a lateral edge of the underfill 2634. A keep out zone (KOZ) 2648 without metallization may be maintained above the fiducial pattern 2642 until a deep cavity is drilled, and by form, the entire height of the dielectric 2616 above the fiducial pattern 2642.

The fiducial pattern, fiducial mark, or just fiducial 2642 has a first doughnut-shaped fiducial portion 2644, although other shapes could be used, and a second fiducial portion 2630 that is a deeper hole under the first portion.

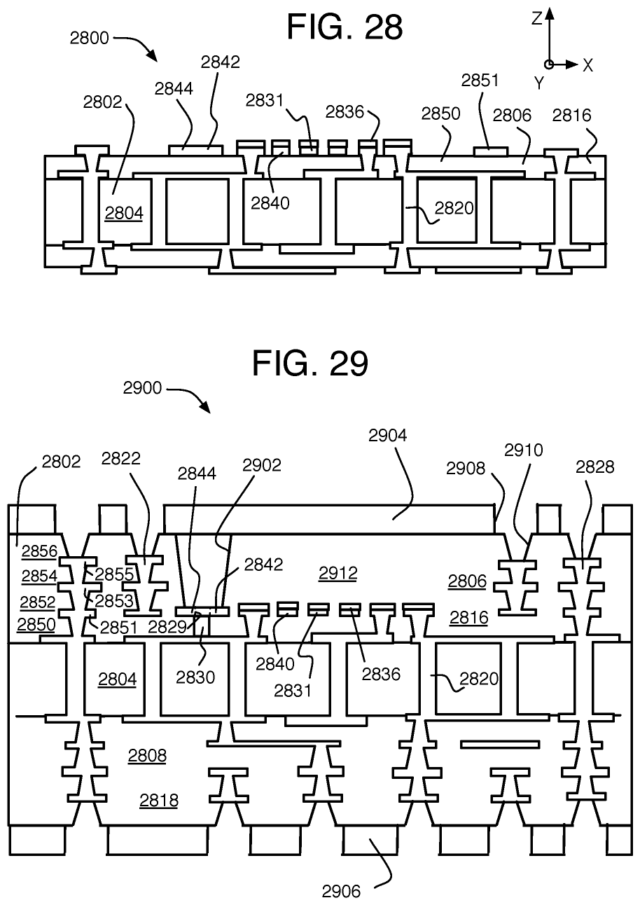

Referring to FIG. 27, the fiducial 2642 may be annular or doughnut-shaped in top view in this example but may be other curved shapes by one form since sharp corners tend to be difficult to pattern and are often blurry in captured images of the fiducial. The first doughnut-shaped portion 2644 has a through hole 2744 at or near a middle of the portion 2644. The second portion or deep hole 2630 may be contiguous or stepped with through-hole 2744 as long as the through-hole and deep hole 2630 cooperatively form a continuous hole or space.

The through-hole 2744 and deep hole 2630 are used as an ideal reference to position a metal layer, and laser drilling can provide a very precise circular opening in dielectric material such as dielectric build-up material described above, which can significantly improve readability since it avoid corners which are difficult to pattern and can cause blurriness.

By one example form, the doughnut portion 2644 may have an outer diameter of 40-310 microns, and the through-hole 2744 (and deep hole 2630) may have a diameter of 30-300 microns. The thickness of the doughnut portion 2644 may be 3-35 microns, and by one form, 15 microns or a thickness that is the same as the conductive features such as pads 2631 on the metallization layer 2651 and metallization pattern 2640.

The deep hole 2630 should be drilled as deep as is practical or efficient. The deeper the hole, the better the contrast with metallization and other elements in an image, and in turn the easier it is to read by imaging tools. By one alternative form, when the deep hole 2630 ends at a metal layer, the metal layer may have a roughened surface 2646 which helps to disperse light for better readability.

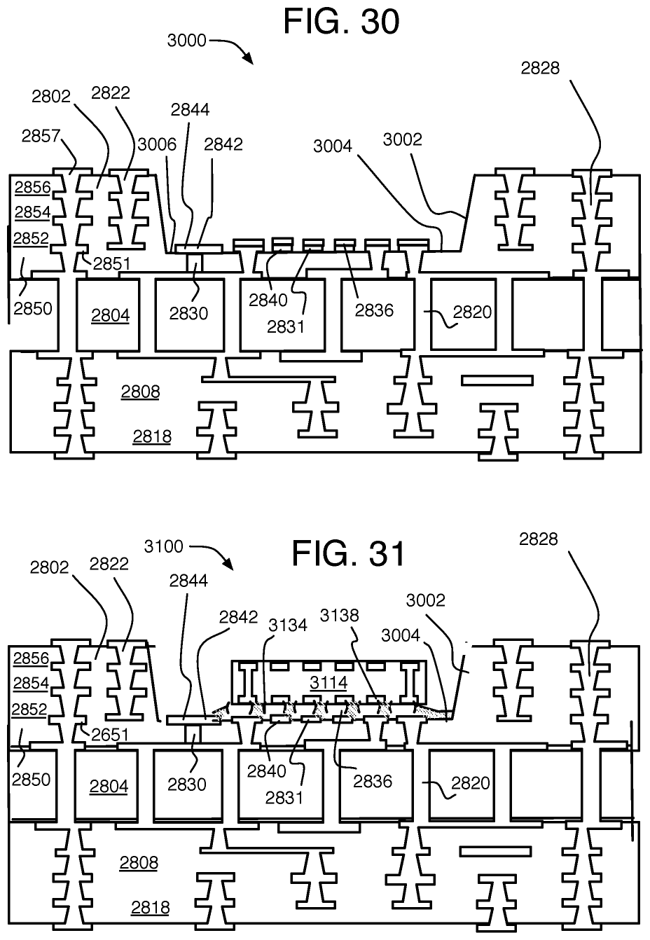

Referring to FIGS. 28-31, a process for assembling IC package 2600 is shown, and particularly for assembling an IC package substrate 2602 with an embedded die and a deep fiducial, in accordance with at least one of the implementations herein. The process stages numbered 2800 to 3100 by multiples of 100 are shown in FIGS. 28-31 merely as one example process, and it will be appreciated that many different process flows may be used in order to provide such an embedded die interconnect layer as described herein.

Referring to FIG. 28, in a stage 2800, an IC package substrate intermediate manufacturing stage 2800 shows a package substrate 2802 with a substrate core 2804, a first or front side 2806 with a dielectric 2816 that has a first or lower dielectric layer 2850 of dielectric material described herein. The items numbered on substrate 2802 are similar to those on substrate 2602 (FIGS. 26) and 102 (FIG. 1) and need not be described in detail here again. Stage 2800 shows that lower dielectric layer 2850 was drilled and then plated with a lower metallization layer 2851.

For a semi-additive electroplating process (SAP), this may include depositing a seed layer, patterning lithographically-defined openings in a photoresist mask, and plating through the opening to build the conductive features of the metallization layer 2851. The metallization layer 2851 may include a metallization pattern or RDL 2840 to be placed under a deep cavity, as well as other metallization of the layer 2851 outside of an area of the cavity to be created yet. The metallization layer 2851 also includes a deep fiducial pattern 2842 with a metal fiducial portion 2844 as described above with fiducial portion 2644, and laterally spaced from the metallization pattern 2840 and area reserved for a die but still within the vicinity or next to the cavity area. The added plating pattern for the SAP may form the fiducial portion 2844 as circular. By one optional form, lithography then may include plating solder 2836, such as tin, on the metallization pattern 2840. The seed then may be etched. By one form, a resist mask may have an annular opening to plate the fiducial. Otherwise, an etching pattern may include exposing a middle of the fiducial portion 2844 to provide a circular through-hole to form a doughnut-shaped body for the fiducial portion 2844 as shown in FIG. 27 with fiducial 2644.

Referring to FIG. 29, in a stage 2900, the remaining dielectric layers 2852, 2854, and upper-most dielectric layer 2856 are stacked over the lower layer 2850. The metallization layers 2853 and 2855 may be placed, but at this point, the metallization of the upper-most dielectric layer 2856 is not in place yet. The build-up of the higher dielectric layers 2852 and 2854 and their metallization can be performed by using the fiducial 2842 for alignment of the lithography layers.

Stage 2900 then shows a deep skive drilling is performed resulting in a fiducial hole 2902 through the upper-most dielectric layer 2856 and down to the fiducial portion 2844. The fiducial hole 2902 is next to, but clear of, a cavity area 2912 reserved for mounting a die in this example. The laser also may skive into a through-hole 2829 on the fiducial portion 2844 to form the deeper hole portion 2830 of the fiducial pattern 2842. Metallization below the deep hole 2830 will act as a laser stop. The laser need not be an excimer laser, and may be a CO2 or other UV laser for example. The fiducial hole 2902 extending down to the fiducial 2842 is drilled for easier imaging of the fiducial during dielectric layer and metallization lithography and plating.

Also in stage 2900, after the fiducial hole 2902 is in place, the metallization on the upper-most layer 2856 may be plated. This involves depositing a resist 2904 (and 2906 on the backside), such as a dry film resist, which is deposited to cover the fiducial hole 2902 to avoid any metal or other material from contacting or blocking the view of the fiducial pattern 2842. Thereafter, holes 2908 may be patterned on the resist to provide the locations for via drilling down to the existing interconnects 2822 and 2828 or other metallization.

Referring to FIG. 30, in a stage 3000, the vias and metallization layer 2857 is plated and the resist 2904 is stripped. Next, the deep cavity 3002 may be drilled, and this may be performed by an excimer laser, although other lasers may be used with a laser stop in the cavity for example. The skiving of the laser is set to be wide enough to ablate the dielectric material between the fiducial hole 2902 and the cavity area 2912 thereby opening the hole 2902 and adding it as part of the cavity 3002. This results in the area of an upper surface 3006 of the lower dielectric layer 2850 next to the fiducial pattern 2842 becoming part of the bottom surface 3004 of the cavity 3002. However, the fiducial 2842 could have been kept in the separate hole 2902 instead of within the cavity 3002 itself, and/or may be placed in a different convenient or efficient position on the package substrate 2802.

Referring to FIG. 31, in a stage 3100, a die 3114 is placed in the cavity to couple die contacts or conductive features 3138 to metallization pattern 2840 through solder 2836, and coupled as described above with substrate 2602, 102 or other implementations herein. Optionally, a non-solder hybrid bonding could be used instead. The die 3114 then may be embedded by further dielectric, and then solder resist and upper underfill layers under upper dies to be coupled to the embedded die 3114, resulting in substrate 2600 (FIG. 26). The details for these subsequent operations are already explained with substrate 102 and 2602 as well as other implementations herein.

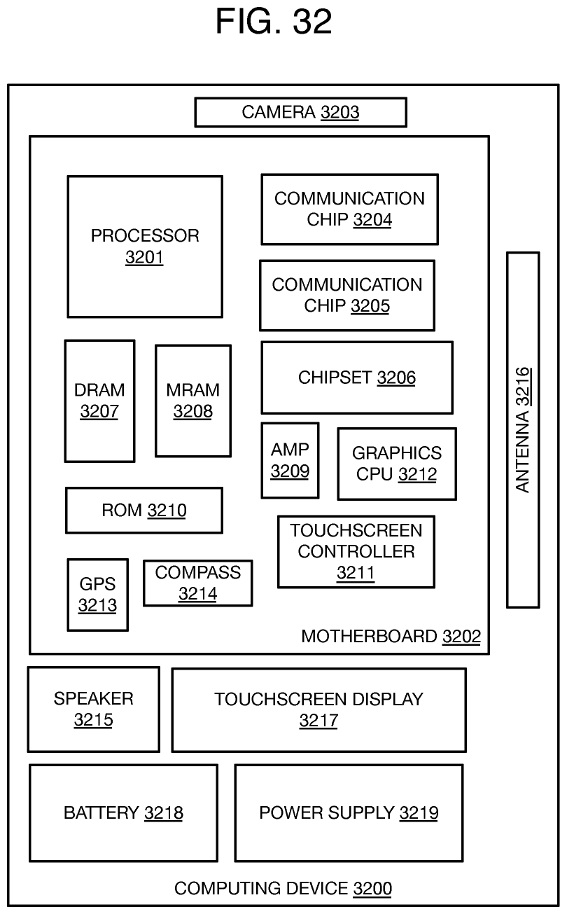

Referring to FIG. 32, an electronic computing device 3200 in accordance with at least one implementation herein of the disclosed devices may have a package substrate or mother board 3202 with a number of components, including but not limited to a processor (e.g., an applications processor) 3201. The processor 3201 may be physically and/or electrically coupled to the package substrate or board 3202. In some implementations, processor 3201 is within a composite IC chip structure, and the processor 3201 may include first circuitry with a package substrate and an embedded die, such as a bridge die, EMIB-T, chiplet, or other die as described herein, for example. Processor 3201 may be implemented with circuitry in either or both of the host IC chips and chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 3204 and 3205 also may be physically and/or electrically coupled to the package substrate or board 3202. In further implementations, communication chips 3204 and 3205 may be part of processor 3201. Depending on its applications, computing device 3200 may include other components that may or may not be physically and electrically coupled to package substrate or board 3202. These other components include, but are not limited to, volatile memory (e.g., DRAM 3207), non-volatile memory (e.g., ROM 3210), flash memory (e.g., NAND or NOR), magnetic memory (MRAM 3208), a graphics processor (CPU) 3212, a digital signal processor, a crypto processor, a chipset 3206, an antenna 3216, touchscreen display 3217, touchscreen controller 3211, battery unit 3218, audio codec, video codec, power amplifier 3209, global positioning system (GPS) device 3213, compass 3214, accelerometer, gyroscope, speaker 3215, camera 3203, and mass storage device (such as hard disk drive, solid-state drive (SSD), compact disk (CD), digital versatile disk (DVD), and so forth), and a power supply unit 3219, or the like. In some exemplary implementations, any of the IC structures, architecture, or units on device 3200 or described in any of the units mentioned above, may have the interconnect structure described above. Thus, for example, in addition to being formed by circuitry of processor 3201, or a composite IC chip of processor 3201, the dies bridged by a second die or chiplet as described herein, also or instead may be implemented by an electronic memory (e.g., MRAM 3208 or DRAM 3207).

The communication chips 3204 and 3205 may enable wireless communications for the transfer of data to and from the computing device 3200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some implementations the devices might not. The communication chip 3204 may implement any of a number of short-range wireless standards or protocols, including but not limited to Wi-Fi (IEEE 3802.11 family), Bluetooth, and others, and communications chip 3205 may implement longer-range wireless standards or protocols such as WiMAX (IEEE 3802.16 family), IEEE 3802.20, long term evolution (LTE), Ev-DO, HSPA+, HSDPA+, HSUPA+, EDGE, GSM, GPRS, CDMA, TDMA, DECT, derivatives thereof, as well as any other wireless protocols that are designated as 3G, 4G, 5G, and beyond.

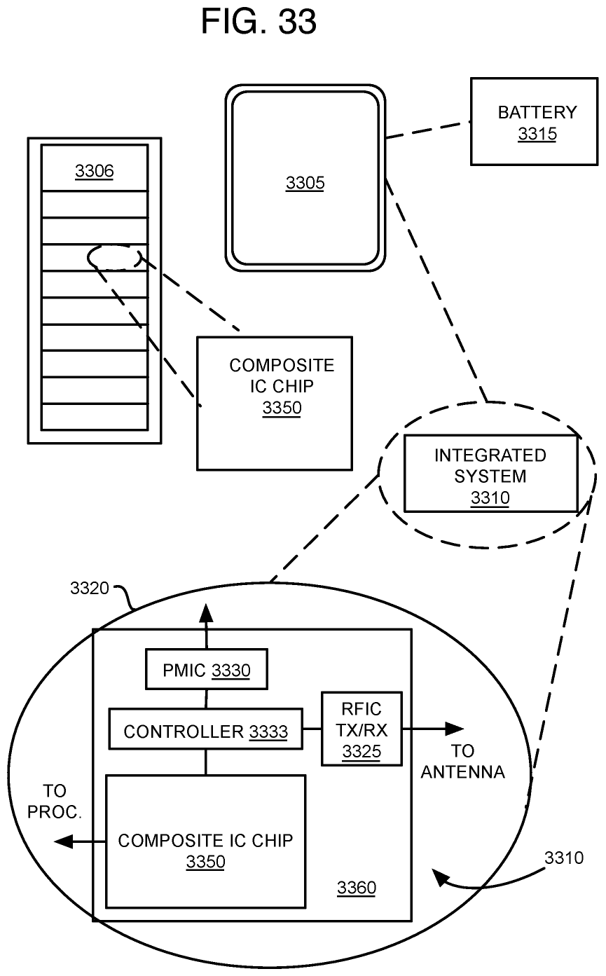

Referring to FIG. 33, a mobile computing platform 3305 and a data server machine 3306 employing an IC device included on a package substrate 3360 as described elsewhere herein. Computing device 100, 2600, and any of the variations or alternative structures mentioned herein may be found inside platform 3305 or server machine 3306, for example. The server machine 3306 may be any commercial server, for example including any number of high-performance computing platforms disposed within a rack and networked together for electronic data processing, which in the exemplary implementation includes structure of at least one IC die assembly on substrate 3360 and used to embed bridge die, for example as described elsewhere herein, and may include a chiplet bonded to multiple die over a host IC chip and/or the package substrate 3360. The mobile computing platform 3305 may be any portable device configured for each of electronic data display, electronic data processing, wireless electronic data transmission, or the like. For example, the mobile computing platform 3305 may be any of a tablet, a smart phone, laptop computer, etc., and may include a display screen (e.g., a capacitive, inductive, resistive, or optical touchscreen), a chip-level or package-level integrated system 3310, and a battery 3315.

Whether disposed within the integrated system 3310 illustrated in the expanded view 3320, or as a stand-alone package within the server machine 3306, composite IC chip 3350 may include a package substrate with an embedded die, which may be a bridge die or chiplet bonded to multiple dies, for example as described elsewhere herein. Composite IC chip 3350 may be further coupled to or over package substrate 3360 and may comprise one or more of a power management integrated circuit (PMIC) 3330, RF (wireless) integrated circuit (RFIC) 3325 including a wideband RF (wireless) transmitter and/or receiver (TX/RX) (e.g., including a digital baseband and an analog front end module further comprises a power amplifier on a transmit path and a low noise amplifier on a receive path), and a controller 3335. PMIC 3330 may perform battery power regulation, DC-to-DC conversion, etc., and so has an input coupled to battery 3315 and with an output providing a current supply to other functional modules. As further illustrated, in the exemplary implementation, RFIC 3325 may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDcPA+, HSUPA+, EDGE, GSM, GPRS, CDMA, TDMA, DECT, Bluetooth, derivatives thereof, as well as any other wireless protocols that are designated as 3G, 4G, 4G, and beyond. Any of these IC units or components over the substrate may include the package substrate with an embedded die that may be a bridge die, chiplet, and/or EMIB-T with one or more interconnects to other die as described herein.

It is understood that the subject matter of the present description is not necessarily limited to specific applications illustrated in FIGS. 1-33. The subject matter may be applied to other electronic, microelectronic, or integrated circuit (IC) devices and assembly applications, as well as any appropriate electronic application, as will be understood to those skilled in the art.

The following examples pertain to further implementations. Specifics in the examples may be used anywhere in one or more implementations.

In an example 1, an electronic package comprises a substrate core; one or more dielectric material layers over the substrate core and having a lower dielectric material layer, and a plurality of metallization layers comprising an upper-most metallization layer; an integrated circuit (IC) die embedded within the dielectric material layers and below the upper-most metallization layer; at least one conductive feature below and coupled to the IC die, wherein a downwardly facing surface of the conductive feature is located on the lower dielectric material layer and defines a horizontal plane at a junction between the conductive feature and the lower dielectric material layer, and wherein the lower dielectric material layer has an upper facing surface facing in a direction of the IC die adjacent the conductive feature that is vertically offset from the horizontal plane.

In an example 2, the subject matter of example 1, wherein the offset is at least 1 micron.

In an example 3, the subject matter of example 1 or 2, wherein the horizontal plane is also defined by the junction between the lower dielectric material layer and a next higher dielectric material layer of the one or more dielectric material layers.

In an example 4, the subject matter of example 2 or 3, wherein the upper surface comprises two portions proximate at least two adjacent conductive features and a middle portion between the two proximate portions and being a different offset from the horizontal plane than the offset of the proximate portions.

In an example 5, the subject matter of any one of examples 1 to 4, wherein the upper surface is between multiple adjacent pairs of the conductive features, and wherein the offset is different between individual pairs of the conductive features.

In an example 6, the subject matter of any one of examples 1 to 5, wherein the metallization pattern comprises a redistribution layer (RDL).

In an example 7, the subject matter of any one of examples 1 to 6, wherein the IC die is a first die, and the electronic package comprising multiple embedded dies including at least one second die having a bottom surface physically adhered to a metal base layer extending at least a width of the bottom surface of the second die, wherein the first and second die are within at least one same dielectric material layer.

In an example 8, the subject matter of any one of examples 1 to 7, wherein the at least one conductive feature comprises multiple conductive features of a metallization pattern, and wherein the electronic packages comprises a member extending horizontally around the metallization pattern and having an inner surface laterally engaging an underfill material between the IC die and the lower dielectric material layer.

In an example 9, the subject matter of any one of examples 1 to 8, comprising at least one hybrid bonding interconnect wherein the at least one conductive feature connects directly to at least one die conductive feature at a bottom of the IC die.

In an example 10, the subject matter of any one of examples 1 to 9, wherein the IC die is at least one of: a bridge die, an embedded multi-die interconnect bridge with through silicon via (EMIB-T), or a chiplet.

In an example 11, a method of manufacturing an electronic package, comprises receiving an IC package substrate core; stacking a plurality of dielectric material layers over the substrate core and from a lower dielectric material layer to an upper-most dielectric material layer, the stacking comprising placing a lower metallization layer on or within the lower dielectric material layer; drilling a cavity with an excimer laser through the upper-most dielectric material layer and comprising uncovering the lower dielectric material layer with the laser; coupling an integrated circuit (IC) die to the lower metallization layer in the cavity; and covering the die in a dielectric material.

In an example 12, the subject matter of example 11, wherein the drilling comprises uncovering separate multiple conductive pads of the lower metallization layer.

In an example 13, the subject matter of example 11 or 12, wherein one of the dielectric material layers covering the multiple conductive pads is in direct contact with the multiple conductive pads before the cavity is drilled.

In an example 14, the subject matter of example 11 or 12, comprising drilling via holes at a bottom of the cavity, and adding conductive features in the holes and that extend upward into the cavity, and wherein the coupling comprises coupling the IC die to the lower metallization layer through the conductive features.

In an example 15, the subject matter of any one of examples 10 to 14, comprising forming a doughnut-shaped metal fiducial on the lower metallization layer and having a through-hole, and wherein the stacking comprises depositing a next dielectric material layer over the fiducial; and before drilling the cavity, drilling, with a laser, a first hole from the upper-most dielectric material layer and sufficiently wide to uncover at least part of the fiducial, the drilling comprising drilling through the through-hole to form a deeper hole under the fiducial, and wherein the drilling of the cavity combines the first hole and the cavity so that the fiducial is disposed within the cavity.

In an example 16, an electronic system, comprising: a substrate core; one or more dielectric material layers over the substrate core and having a plurality of metallization layers comprising an upper-most metallization layer and a lower metallization layer; and an integrated circuit (IC) die having one or more die conductive features and being at least partially embedded within the dielectric material below the upper-most metallization layer, wherein the lower metallization layer comprises a plurality of pads including at least one first pad under the IC die and coupled to the die conductive features, and at least one second pad of the lower metallization layer spaced laterally away from the IC die, and wherein a thickness of the first pad is different than a thickness of the second pad.

In an example 17, the subject matter of example 16, wherein the at least one first and second pad comprise a plurality of first and second pads, and the plurality of first pads is thicker than the plurality of second pads.

In an example 18, the subject matter of example 16 or 17, wherein the one or more dielectric material layers comprises a lower dielectric material layer lower than the IC die, and wherein the at least one first pad comprises a downwardly facing surface engaging the lower dielectric material layer and defining a horizontal plane at the junction between the first pad and lower dielectric material layer, and wherein the lower dielectric material layer has an upper surface facing in a direction of the IC die adjacent the first pad and is vertically offset from the horizontal plane.

In an example 19, the subject matter of any one of examples 16 to 18, comprising a fiducial pattern having a groove extending downward from an upper surface of the upper-most dielectric material layer in proximity to the embedded die, and a raised metal member on the upper surface and near the hole, wherein the fiducial pattern is only on the upper-most dielectric material layer.

In an example 20, the subject matter of any one of examples 16 to 19, comprising wherein the one or more dielectric material layers comprises a lower dielectric material layer having the lower metallization layer, and the system comprising a fiducial pattern at the lower metallization layer comprising a first portion having a doughnut shape with a vertically extending through-hole and being formed of metal, and a second portion being a deeper hole in the lower dielectric material layer and being arranged under the through-hole, wherein the through-hole and deeper hole cooperatively provide a continuous hole.

In an example 21, a method of manufacturing an IC package comprises receiving an IC package substrate core; stacking a plurality of dielectric material layers over the substrate core, and from a lower dielectric layer to an upper-most dielectric material layer; laser drilling a cavity from the upper-most dielectric material layer to a bottom surface of the cavity at the lower dielectric material layer; placing vias in the holes and via pads on the vias and on the bottom surface of the cavity; and attaching a die to the via pads

In an example 22, a method of manufacturing an IC package comprises receiving an IC package substrate core; placing a lower dielectric layer over the substrate core and having a first layer of conductive material over, and coupling to, multiple separate conductive features; stacking a plurality of dielectric material layers over the first layer; laser drilling a cavity from the upper-most dielectric material layer to the first layer; dividing the first layer between the conductive features and into at least two portions that each is coupled to at least one different conductive feature of the multiple separate conductive features; and attach a die to the portions.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

1-20. (canceled)

21. An electronic package, comprising:
one or more dielectric material layers and a plurality of metallization layers over a substrate core, the one or more dielectric material layers having a lower dielectric material layer, and the plurality of metallization layers having an upper-most metallization layer;
an integrated circuit (IC) die embedded within the dielectric material layers and the metallization layers, the IC die below the upper-most metallization layer; and
a conductive feature below and coupled to the IC die, wherein a downwardly facing surface of the conductive feature is on the lower dielectric material layer and defines a horizontal plane at a junction between the conductive feature and the lower dielectric material layer, and
wherein the lower dielectric material layer has an upper facing surface facing in a direction of the IC die adjacent the conductive feature that is vertically offset from the horizontal plane.

22. The electronic package of claim 21, wherein the offset is at least 1 micron.

23. The electronic package of claim 21, wherein the horizontal plane is further defined by a junction between the lower dielectric material layer and a next higher dielectric material layer of the one or more dielectric material layers.

24. The electronic package of claim 21, wherein the upper facing surface comprises two portions proximate at least two adjacent conductive features and a middle portion between the two proximate portions and being a different offset from the horizontal plane than the offset of the proximate portions.

25. The electronic package of claim 21, wherein the upper facing surface is between multiple adjacent pairs of the conductive features, and wherein the offset is different between individual pairs of the conductive features.

26. The electronic package of claim 21, wherein the metallization layers comprise a redistribution layer (RDL).

27. The electronic package of claim 21, wherein the IC die is a first IC die, and the electronic package comprises multiple embedded IC dies comprising at least one second IC die having a bottom surface physically adhered to a metal base layer extending at least a width of the bottom surface of the second IC die, wherein the first IC die and the second IC die are within at least one same dielectric material layer.

28. The electronic package of claim 21, wherein the conductive feature comprises multiple conductive features of a metallization pattern, and wherein the electronic package comprises a member extending horizontally around the metallization pattern and having an inner surface laterally engaging an underfill material between the IC die and the lower dielectric material layer.

29. The electronic package of claim 21, further comprising at least one hybrid bonding interconnect, wherein the at least one conductive feature connects directly to at least one conductive feature at a bottom of the IC die.

30. The electronic package of claim 21, wherein the IC die is at least one of a bridge die, an embedded multi-die interconnect bridge with through silicon vias (EMIB-T), or a chiplet.

31. A method of manufacturing an electronic package, comprising:
stacking a plurality of dielectric material layers and a plurality of metallization layers over an IC package substrate core, wherein the stacking forms a lower dielectric material layer to an upper-most dielectric material layer, and places a lower metallization layer on or within the lower dielectric material layer;
drilling a cavity with an excimer laser through the upper-most dielectric material layer and uncovering the lower dielectric material layer with the laser;
coupling an integrated circuit (IC) die to the lower metallization layer in the cavity; and
covering the IC die with a dielectric material.

32. The method of claim 31, wherein the drilling comprises uncovering separate multiple conductive pads of the lower metallization layer.

33. The method of claim 32, wherein one of the dielectric material layers covering the multiple conductive pads is in direct contact with the multiple conductive pads before the cavity is drilled.

34. The method of claim 31, further comprising drilling via holes at a bottom of the cavity, and forming conductive features in the holes that extend upward into the cavity, and wherein the coupling comprises coupling the IC die to the lower metallization layer through the conductive features.

35. The method of claim 31, further comprising:
forming a doughnut-shaped metal fiducial on the lower metallization layer and having a through-hole, and wherein the stacking comprises depositing a next dielectric material layer over the fiducial; and
before drilling the cavity, drilling, with a laser, a first hole from the upper-most dielectric material layer and sufficiently wide to uncover at least part of the fiducial, the drilling comprising drilling through the through-hole to form a deeper hole under the fiducial, and
wherein the drilling of the cavity combines the first hole and the cavity so that the fiducial is disposed within the cavity.

36. An electronic system, comprising:
one or more dielectric material layers and a plurality of metallization layers over a substrate core, the plurality of metallization layers comprising an upper-most metallization layer and a lower metallization layer; and
an integrated circuit (IC) die having one or more die conductive features and being at least partially embedded within the dielectric material below the upper-most metallization layer,
wherein the lower metallization layer comprises a plurality of pads comprising at least one first pad under the IC die and coupled to the die conductive features, and at least one second pad spaced laterally away from the IC die, wherein a thickness of the first pad is different than a thickness of the second pad.

37. The system of claim 36, wherein the at least one first and second pad comprise a plurality of first and second pads, and the plurality of first pads is thicker than the plurality of second pads.

38. The system of claim 36, wherein the one or more dielectric material layers comprises a lower dielectric material layer lower than the IC die, and wherein the at least one first pad comprises a downwardly facing surface engaging the lower dielectric material layer and defining a horizontal plane at a junction between the first pad and lower dielectric material layer, and wherein the lower dielectric material layer has an upper surface facing in a direction of the IC die adjacent the first pad that is vertically offset from the horizontal plane.

39. The system of claim 36, further comprising a fiducial pattern having a groove extending downward from an upper surface of an upper-most dielectric material layer in proximity to the embedded die, and a raised metal member on the upper surface and near a hole, wherein the fiducial pattern is only on the upper-most dielectric material layer.

40. The system of claim 36, wherein the one or more dielectric material layers comprises a lower dielectric material layer comprising the lower metallization layer, and the system further comprises a fiducial pattern at the lower metallization layer comprising a first portion having a doughnut shape with a vertically extending through-hole and being formed of metal, and a second portion being a deeper hole in the lower dielectric material layer and being arranged under the through-hole, wherein the through-hole and deeper hole cooperatively provide a continuous hole.
